(19) United States
(12) Patent Application Publication
(10) Pub. No.: US 2024/0014928 A1
(43) Pub. Date: Jan. 11, 2024

(54) GENERATION OF CODED PSEUDORANDOM SEQUENCES

(71) Applicant: QUALCOMM Incorporated, San Diego, CA (US)

(72) Inventors: Jing Lei, San Diego, CA (US); Wei Yang, San Diego, CA (US); Jing Jiang, San Diego, CA (US); Yongle Wu, San Diego, CA (US)

(21) Appl. No.: 18/157,991

(22) Filed: Jan. 23, 2023

Related U.S. Application Data
(60) Provisional application No. 63/359,670, filed on Jul. 8, 2022.

(51) Int. Cl. H04L 1/00; H03M 13/15

(52) U.S. Cl. CPC H04L 1/0041; H04L 1/0057; H03M 13/151

(57) ABSTRACT

Methods, systems, and devices for wireless communication are described. A wireless device may generate a coded pseudorandom using an encoder that implements error detection and/or error correction techniques. A bit sequence of information bits may be segmented into a plurality of bit groups, and each bit group may be mapped to a respective symbol to generate a plurality of ordered information symbols. The plurality of ordered information symbols may be encoded (e.g., by the encoder) to generate a plurality of codewords. Each codeword may be demapped to generate a plurality of sequences that are multiplexed to generate the pseudorandom sequence. A signal that is generated based on the pseudorandom sequence may be transmitted by the wireless device. In some examples, the wireless device may generate a reference signal based on orthogonal or pseudo-orthogonal random sequences generated by applying an orthogonal cover code to a pseudorandom sequence.

### CROSS REFERENCE

The present Application for Patent claims the benefit of U.S. Provisional Patent Application No. 63/359,670 by LEI et al., entitled “GENERATION OF CODED PSEUDORANDOM SEQUENCES,” filed Jul. 8, 2022, assigned to the assignee hereof, and expressly incorporated by reference herein.

### TECHNICAL FIELD

The following relates to wireless communication, including generation of coded pseudorandom sequences.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

Devices of a wireless communications system, such as UEs and network entities, may use pseudorandom number generation techniques to support encoding and decoding of information. Some pseudorandom number generation techniques may be subject to cross-correlation and may be limited in the amount of information that the generated pseudorandom numbers can carry.

### SUMMARY

The described techniques relate to improved methods, systems, devices, and apparatuses that support generation of coded pseudorandom sequences. For example, the described techniques provide for coded pseudorandom sequence generation by a wireless device that uses an encoder implementing error detection and/or error correction techniques. A bit sequence of information bits may be segmented into a plurality of bit groups, and each bit group may be mapped to a respective symbol to generate a plurality of ordered information symbols. The plurality of ordered information symbols may be encoded (e.g., by the encoder) to generate a plurality of codewords. Each codeword may be demapped to generate a plurality of sequences that are multiplexed to generate the pseudorandom sequence. A signal that is generated based on the pseudorandom sequence may be transmitted by the wireless device.

The described techniques also support use of an orthogonal cover code (OCC) that is applied to a pseudorandom sequence to generate orthogonal or pseudo-orthogonal sequences. Ordered information bits may be segmented into bit subsets, and an OCC may be generated based on a bit subset. The OCC is applied to an input pseudorandom sequence to generate the plurality of orthogonal or pseudo-orthogonal sequences. A reference signal may be generated based on the plurality of orthogonal or pseudo-orthogonal sequences.

A method for wireless communication at a wireless device is described. The method may include segmenting a bit sequence of information bits into a set of multiple bit groups, mapping each bit group of the set of multiple bit groups to a respective symbol to generate a set of multiple ordered information symbols, encoding the set of multiple ordered information symbols to generate a set of multiple codewords, demapping each codeword of the set of multiple codewords to generate a set of multiple sequences, multiplexing the set of multiple sequences to generate a pseudorandom sequence, and transmitting a signal generated based on the pseudorandom sequence.

An apparatus for wireless communication at a wireless device is described. The apparatus may include a processor and memory coupled with the processor, the memory storing instructions that may be for the processor to cause the wireless device to segment a bit sequence of information bits into a set of multiple bit groups, mapping each bit group of the set of multiple bit groups to a respective symbol to generate a set of multiple ordered information symbols, encode the set of multiple ordered information symbols to generate a set of multiple codewords, demap each codeword of the set of multiple codewords to generate a set of multiple sequences, multiplex the set of multiple sequences to generate a pseudorandom sequence, and transmit a signal generated based on the pseudorandom sequence.

Another apparatus for wireless communication at a wireless device is described. The apparatus may include means for segmenting a bit sequence of information bits into a set of multiple bit groups, means for mapping each bit group of the set of multiple bit groups to a respective symbol to generate a set of multiple ordered information symbols, means for encoding the set of multiple ordered information symbols to generate a set of multiple codewords, means for demapping each codeword of the set of multiple codewords to generate a set of multiple sequences, means for multiplexing the set of multiple sequences to generate a pseudorandom sequence, and means for transmitting a signal generated based on the pseudorandom sequence.

A non-transitory computer-readable medium storing code for wireless communication at a wireless device is described. The code may include instructions for a processor to cause the wireless device to segment a bit sequence of information bits into a set of multiple bit groups, mapping each bit group of the set of multiple bit groups to a respective symbol to generate a set of multiple ordered information symbols, encode the set of multiple ordered information symbols to generate a set of multiple codewords, demap each codeword of the set of multiple codewords to generate a set of multiple sequences, multiplex the set of multiple sequences to generate a pseudorandom sequence, and transmit a signal generated based on the pseudorandom sequence.

Some examples of the method, apparatuses, and non-transitory computer-readable medium described herein may further include operations, features, means, or instructions for receiving control signaling that indicates that the wireless device may be to use single-stage randomization or multi-stage randomization, where the pseudorandom sequence may be generated based on multi-stage randomization.

Some examples of the method, apparatuses, and non-transitory computer-readable medium described herein may further include operations, features, means, or instructions for receiving control signaling that indicates that the wireless device may be to use an OCC to generate a set of multiple orthogonal sequences based on the pseudorandom sequence, where the signal may be generated based on the OCC.

Some examples of the method, apparatuses, and non-transitory computer-readable medium described herein may further include operations, features, means, or instructions for receiving control signaling that indicates a configuration for generating the pseudorandom sequence, where pseudorandom sequence may be generated based on the configuration.

In some examples of the method, apparatuses, and non-transitory computer-readable medium described herein, encoding the set of multiple ordered information symbols may include operations, features, means, or instructions for encoding the set of multiple ordered information symbols using a codebook associated with an error detection code or an error correction code and generating a codeword including information symbols of the set of multiple ordered information symbols and a set of multiple check symbols, where the check symbols include cyclic redundancy check (CRC) symbols of the error detection code, parity check symbols of the error correction code, or a combination thereof.

In some examples of the method, apparatuses, and non-transitory computer-readable medium described herein, codewords in the codebook may have a defined separation distance for a given code rate or a given codebook size.

In some examples of the method, apparatuses, and non-transitory computer-readable medium described herein, the codeword may be generated using an error detection coding algorithm that may be a Reed-Solomon code or a Bose-Chaudhuri-Hocquenghem code.

In some examples of the method, apparatuses, and non-transitory computer-readable medium described herein, each subset of information bits of a set of multiple subsets of information bits may be zero padded, each subset of information bits corresponding to an information symbol defined on a finite field, where the zero-padding results in the bit sequence of information bits.

Some examples of the method, apparatuses, and non-transitory computer-readable medium described herein may further include operations, features, means, or instructions for processing a set of multiple subsets of information bits, each subset of information bits corresponding to an information symbol, the processing including multiplexing, interleaving, or both the set of multiple subsets of information bits resulting in the set of multiple ordered information symbols.

Some examples of the method, apparatuses, and non-transitory computer-readable medium described herein may further include operations, features, means, or instructions for initializing a second pseudorandom sequence generator based on the pseudorandom sequence, where elements of the pseudorandom sequence may be binary or non-binary.

In some examples of the method, apparatuses, and non-transitory computer-readable medium described herein, the second pseudorandom sequence generator includes one or more linear-feedback shift registers and operation of the one or more linear-feedback shift registers may be defined on a binary finite field or a non-binary finite field.

In some examples of the method, apparatuses, and non-transitory computer-readable medium described herein, initializing the second pseudorandom sequence generator may include operations, features, means, or instructions for using the pseudorandom sequence that may be coded and includes a set of multiple information symbols and check symbols as input into the initialized second pseudorandom sequence generator.

Some examples of the method, apparatuses, and non-transitory computer-readable medium described herein may further include operations, features, means, or instructions for generating a set of multiple bit subsets based on a set of multiple ordered information bits, generating an OCC based on a first subset of the set of multiple bit subsets, applying the OCC to the pseudorandom sequence to generate a set of multiple orthogonal or pseudo-orthogonal random sequences, and generating a reference signal based on the set of multiple orthogonal or pseudo-orthogonal random sequences.

Some examples of the method, apparatuses, and non-transitory computer-readable medium described herein may further include operations, features, means, or instructions for multiplexing the set of multiple orthogonal or pseudo-orthogonal random sequences to generate a multiplexed signal, where the reference signal may be generated based on the multiplexed set of multiple orthogonal or pseudo-orthogonal random sequences.

In some examples of the method, apparatuses, and non-transitory computer-readable medium described herein, generating the OCC may include operations, features, means, or instructions for generating the OCC using a closed-form formula including a Walsh-Hadamard code, a constant amplitude zero autocorrelation waveform sequence, a chirp sequence, or any combination thereof.

In some examples of the method, apparatuses, and non-transitory computer-readable medium described herein, applying the OCC may include operations, features, means, or instructions for multiplying each pseudorandom symbol subset of a set of multiple pseudorandom symbol subsets by a respective symbol of the OCC to generate the set of multiple orthogonal or pseudo-orthogonal random sequences, where the pseudorandom sequence may be segmented to generate the set of multiple pseudorandom symbol subsets.

In some examples of the method, apparatuses, and non-transitory computer-readable medium described herein, applying the OCC may include operations, features, means, or instructions for multiplying each pseudorandom symbol subset of a set of multiple pseudorandom symbol subsets by a respective symbol of the OCC to generate the set of multiple orthogonal or pseudo-orthogonal random sequences, where the pseudorandom sequence may be repeated to generate the set of multiple pseudorandom symbol subsets.

In some examples of the method, apparatuses, and non-transitory computer-readable medium described herein, applying the OCC may include operations, features, means, or instructions for multiplying each pseudorandom symbol subset of a set of multiple pseudorandom symbol subsets by a respective symbol of the OCC to generate the set of multiple orthogonal or pseudo-orthogonal random sequences, where the pseudorandom sequence is concatenated with one or more second pseudorandom sequences to generate the set of multiple pseudorandom symbol subsets.

A method for wireless communication at a wireless device is described. The method may include generating a set of multiple bit subsets based on a set of multiple ordered information bits, generating an OCC based on a first subset of the set of multiple bit subsets, applying the OCC to an input pseudorandom sequence to generate a set of multiple orthogonal or pseudo-orthogonal random sequences, and generating a reference signal based on the set of multiple orthogonal or pseudo-orthogonal random sequences.

An apparatus for wireless communication at a wireless device is described. The apparatus may include a processor and memory coupled with the processor that may be for the processor to cause the wireless device to generate a set of multiple bit subsets based on a set of multiple ordered information bits, generate an OCC based on a first subset of the set of multiple bit subsets, apply the OCC to an input pseudorandom sequence to generate a set of multiple orthogonal or pseudo-orthogonal random sequences, and generate a reference signal based on the set of multiple orthogonal or pseudo-orthogonal random sequences.

Another apparatus for wireless communication at a wireless device is described. The apparatus may include means for generating a set of multiple bit subsets based on a set of multiple ordered information bits, means for generating an OCC based on a first subset of the set of multiple bit subsets, means for applying the OCC to an input pseudorandom sequence to generate a set of multiple orthogonal or pseudo-orthogonal random sequences, and means for generating a reference signal based on the set of multiple orthogonal or pseudo-orthogonal random sequences.

A non-transitory computer-readable medium storing code for wireless communication at a wireless device is described. The code may include instructions for a processor to cause the wireless device to generate a set of multiple bit subsets based on a set of multiple ordered information bits, generate an OCC based on a first subset of the set of multiple bit subsets, apply the OCC to an input pseudorandom sequence to generate a set of multiple orthogonal or pseudo-orthogonal random sequences, and generate a reference signal based on the set of multiple orthogonal or pseudo-orthogonal random sequences.

Some examples of the method, apparatuses, and non-transitory computer-readable medium described herein may further include operations, features, means, or instructions for multiplexing the set of multiple orthogonal or pseudo-orthogonal random sequences to generate a multiplexed signal, where the reference signal may be generated based on the multiplexed set of multiple orthogonal or pseudo-orthogonal random sequences.

In some examples of the method, apparatuses, and non-transitory computer-readable medium described herein, generating the OCC may include operations, features, means, or instructions for generating the OCC using a closed-form formula that may be a Walsh-Hadamard code, or a constant amplitude zero autocorrelation waveform sequence, or a chirp sequence, or any combination thereof.

In some examples of the method, apparatuses, and non-transitory computer-readable medium described herein, applying the OCC may include operations, features, means, or instructions for multiplying each pseudorandom symbol subset of a set of multiple pseudorandom symbol subsets by a respective symbol of the OCC to generate the set of multiple orthogonal or pseudo-orthogonal random sequences, where the input pseudorandom sequence may be segmented to generate the set of multiple pseudorandom symbol subsets.

In some examples of the method, apparatuses, and non-transitory computer-readable medium described herein, applying the OCC may include operations, features, means, or instructions for multiplying each pseudorandom symbol subset of a set of multiple pseudorandom symbol subsets by a respective symbol of the OCC to generate the set of multiple orthogonal or pseudo-orthogonal random sequences, where the input pseudorandom sequence may be repeated to generate the set of multiple pseudorandom symbol subsets.

In some examples of the method, apparatuses, and non-transitory computer-readable medium described herein, applying the OCC may include operations, features, means, or instructions for multiplying each pseudorandom symbol subset of a set of multiple pseudorandom symbol subsets by a respective symbol of the OCC to generate the set of multiple orthogonal or pseudo-orthogonal random sequences, where the input pseudorandom sequence is concatenated with one or more second pseudorandom sequences to generate the set of multiple pseudorandom symbol subsets.

Some examples of the method, apparatuses, and non-transitory computer-readable medium described herein may further include operations, features, means, or instructions for segmenting a bit sequence of information bits into a set of multiple bit groups, mapping each bit group of the set of multiple bit groups to a respective symbol to generate a set of multiple ordered information symbols, encoding the set of multiple ordered information symbols to generate a set of multiple codewords, demapping each codeword of the set of multiple codewords to generate a set of multiple sequences, and multiplexing the set of multiple sequences to generate a pseudorandom sequence that includes the plurality of ordered information symbols.

Some examples of the method, apparatuses, and non-transitory computer-readable medium described herein may further include operations, features, means, or instructions for receiving control signaling indicating a configuration for generating the set of multiple orthogonal or pseudo-orthogonal random sequences, where the set of multiple orthogonal or pseudo-orthogonal random sequences may be generated based on the configuration.

### BRIEF DESCRIPTION OF THE DRAWINGS

FIG. 1 illustrates an example of a wireless communications system that supports generation of coded pseudorandom sequences in accordance with one or more aspects of the present disclosure.

FIG. 2 illustrates an example of a procedure that supports generation of coded pseudorandom sequences in accordance with one or more aspects of the present disclosure.

FIG. 3 illustrates an example of a multi-stage randomization procedure that supports generation of coded pseudorandom sequences in accordance with one or more aspects of the present disclosure.

FIG. 4 illustrates an example of a orthogonal cover code (OCC) procedure that supports generation of coded pseudorandom sequences in accordance with one or more aspects of the present disclosure.

FIG. 5 illustrates an example of a process flow that supports generation of coded pseudorandom sequences in accordance with one or more aspects of the present disclosure.

FIGS. 6 and 7 show block diagrams of devices that support generation of coded pseudorandom sequences in accordance with one or more aspects of the present disclosure.

FIG. 8 shows a block diagram of a communications manager that supports generation of coded pseudorandom sequences in accordance with one or more aspects of the present disclosure.

FIG. 9 shows a diagram of a system including a UE that supports generation of coded pseudorandom sequences in accordance with one or more aspects of the present disclosure.

FIG. 10 shows a diagram of a system including a network entity that supports generation of coded pseudorandom sequences in accordance with one or more aspects of the present disclosure.

FIGS. 11 through 13 show flowcharts illustrating methods that support generation of coded pseudorandom sequences in accordance with one or more aspects of the present disclosure.

### DETAILED DESCRIPTION

Wireless devices, such as user equipments (UEs) and network entities, may encode data using pseudorandom sequence techniques. Pseudorandom sequences may be used to carry small amounts of information bits (e.g., cell identifiers) on downlink, uplink, and/or sidelink signals. Some pseudorandom sequence generation techniques may not be scalable to support higher radio frequency spectrum bands or an increased quantity of cells and/or UEs. Additionally, current pseudorandom sequences may be limited in the amount of information that the sequences can carry and may suffer from cross-correlation, such as in dual port synchronization signal designs.

Techniques described herein support improved pseudorandom sequence generation techniques that may support higher band communication, improved auto-correlation, reduced cross-correlation, and an increase in the amount of cells/devices in a wireless communication environment. The described techniques include a codeword technique for generating a pseudorandom sequence based on information bits. The codeword technique may include segmenting a bit sequence of information bits into a set of bit groups and mapping each bit group of the set of bit groups to a respective symbol to generate a plurality of ordered information symbols. Each symbol may be encoded to a set of codewords, and each codeword may be demapped to generate a plurality of sequences. The plurality of sequences may be multiplexed to generate the pseudorandom sequence, and a signal may be transmitted that is generated based on the pseudorandom sequence.

The techniques described herein may also support multi-stage randomization. For example, the pseudorandom sequence generated using the techniques described herein may be used to initialize a second pseudorandom sequence generator (which may implement the pseudorandom technique described herein or may be one or more linear-feedback shift registers). Multi-stage randomization may support further reduced cross-correlation. Additionally, or alternatively, orthogonal cover code (OCC) techniques may be used to further improve pseudorandom generation techniques. The OCC techniques described herein may support generation of orthogonal or pseudo-orthogonal sequences. These and other techniques are described in further detail with respect to the figures.

Aspects of the disclosure are initially described in the context of wireless communications systems. Aspects of the disclosure are further described with a pseudorandom number generation procedure, a multi-stage pseudorandom number procedure, a OCC procedure, and a process flow diagram. Aspects of the disclosure are further illustrated by and described with reference to apparatus diagrams, system diagrams, and flowcharts that relate to generation of coded pseudorandom sequences.

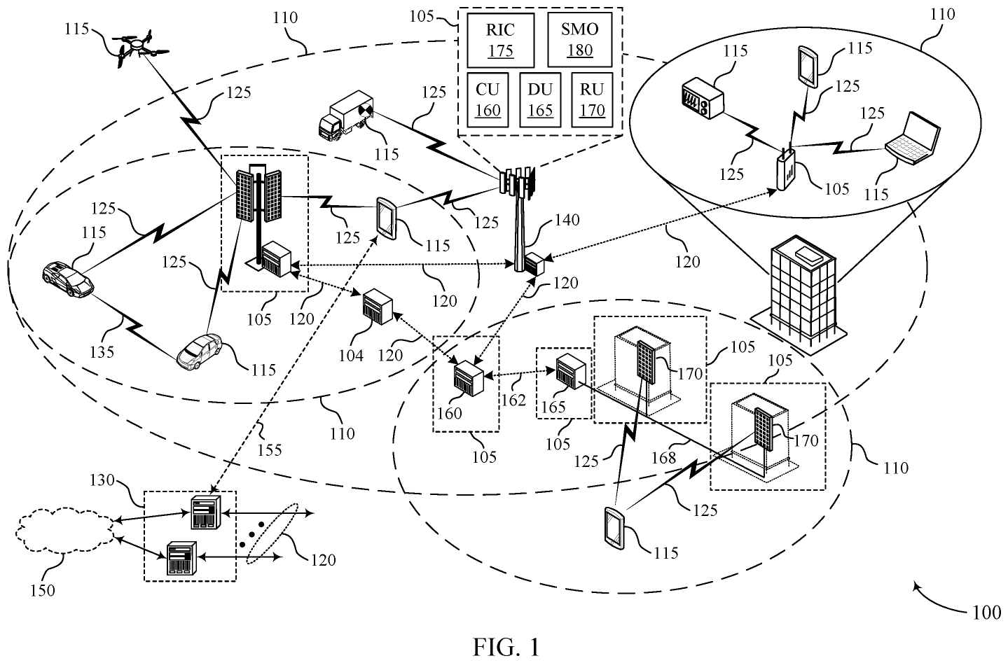

FIG. 1 illustrates an example of a wireless communications system 100 that supports generation of coded pseudorandom sequences in accordance with one or more aspects of the present disclosure. The wireless communications system 100 may include one or more network entities 105, one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via one or more communication links 125 (e.g., a radio frequency (RF) access link). For example, a network entity 105 may support a coverage area 110 (e.g., a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, or computing system may include disclosure of the UE 115, network entity 105, apparatus, device, or computing system being a node. For example, disclosure that a UE 115 is configured to receive information from a network entity 105 also discloses that a first node is configured to receive information from a second node.

In some examples, network entities 105 may communicate with the core network 130, or with one another, or both. For example, network entities 105 may communicate with the core network 130 via one or more backhaul communication links 120 (e.g., in accordance with an S1, N2, N3, or other interface protocol). In some examples, network entities 105 may communicate with one another via a backhaul communication link 120 (e.g., in accordance with an X2, Xn, or other interface protocol) either directly (e.g., directly between network entities 105) or indirectly (e.g., via a core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication links 120, midhaul communication links 162, or fronthaul communication links 168 may be or include one or more wired links (e.g., an electrical link, an optical fiber link), one or more wireless links (e.g., a radio link, a wireless optical link), among other examples or various combinations thereof. A UE 115 may communicate with the core network 130 via a communication link 155. Components within a wireless communication system may be coupled (for example, operatively, communicatively, functionally, electronically, and/or electrically) to each other.

One or more of the network entities 105 described herein may include or may be referred to as a base station 140 (e.g., a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within a single network entity 105 (e.g., a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU) 160, a distributed unit (DU) 165, a radio unit (RU) 170, a RAN Intelligent Controller (MC) 175 (e.g., a Near-Real Time MC (Near-RT RIC), a Non-Real Time MC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or more RUs 170). In some cases, a functional split between a CU 160 and a DU 165, or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (e.g., F1, F1-c, F1-u), and a DU 165 may be connected to one or more RUs 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities 105 that are in communication via such communication links.

In wireless communications systems (e.g., wireless communications system 100), infrastructure and spectral resources for radio access may support wireless backhaul link capabilities to supplement wired backhaul connections, providing an IAB network architecture (e.g., to a core network 130). In some cases, in an IAB network, one or more network entities 105 (e.g., IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (e.g., a donor base station 140). The one or more donor network entities 105 (e.g., IAB donors) may be in communication with one or more additional network entities 105 (e.g., IAB nodes 104) via supported access and backhaul links (e.g., backhaul communication links 120). IAB nodes 104 may include an IAB mobile termination (IAB-MT) controlled (e.g., scheduled) by DUs 165 of a coupled IAB donor. An IAB-MT may include an independent set of antennas for relay of communications with UEs 115, or may share the same antennas (e.g., of an RU 170) of an IAB node 104 used for access via the DU 165 of the IAB node 104 (e.g., referred to as virtual IAB-MT (vIAB-MT)). In some examples, the IAB nodes 104 may include DUs 165 that support communication links with additional entities (e.g., IAB nodes 104, UEs 115) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

In the case of the techniques described herein applied in the context of a disaggregated RAN architecture, one or more components of the disaggregated RAN architecture may be configured to support generation of coded pseudorandom sequences as described herein. For example, some operations described as being performed by a UE 115 or a network entity 105 (e.g., a base station 140) may additionally, or alternatively, be performed by one or more components of the disaggregated RAN architecture (e.g., IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a multimedia/entertainment device (e.g., a radio, a MP3 player, or a video device), a camera, a gaming device, a navigation/positioning device (e.g., GNSS (global navigation satellite system) devices based on, for example, GPS (global positioning system), Beidou, GLONASS, or Galileo, or a terrestrial-based device), a tablet computer, a laptop computer, a netbook, a smartbook, a personal computer, a smart device, a wearable device (e.g., a smart watch, smart clothing, smart glasses, virtual reality goggles, a smart wristband, smart jewelry (e.g., a smart ring, a smart bracelet)), a drone, a robot/robotic device, a vehicle, a vehicular device, a meter (e.g., parking meter, electric meter, gas meter, water meter), a monitor, a gas pump, an appliance (e.g., kitchen appliance, washing machine, dryer), a location tag, a medical/healthcare device, an implant, a sensor/actuator, a display, or any other suitable device configured to communicate via a wireless or wired medium. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (e.g., an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities 105).

In some examples, such as in a carrier aggregation configuration, a carrier may also have acquisition signaling or control signaling that coordinates operations for other carriers. A carrier may be associated with a frequency channel (e.g., an evolved universal mobile telecommunication system terrestrial radio access (E-UTRA) absolute RF channel number (EARFCN)) and may be identified according to a channel raster for discovery by the UEs 115. A carrier may be operated in a standalone mode, in which case initial acquisition and connection may be conducted by the UEs 115 via the carrier, or the carrier may be operated in a non-standalone mode, in which case a connection is anchored using a different carrier (e.g., of the same or a different radio access technology).

The communication links 125 shown in the wireless communications system 100 may include downlink transmissions (e.g., forward link transmissions) from a network entity 105 to a UE 115, uplink transmissions (e.g., return link transmissions) from a UE 115 to a network entity 105, or both, among other configurations of transmissions. Carriers may carry downlink or uplink communications (e.g., in an FDD mode) or may be configured to carry downlink and uplink communications (e.g., in a TDD mode).

A carrier may be associated with a particular bandwidth of the RF spectrum and, in some examples, the carrier bandwidth may be referred to as a “system bandwidth” of the carrier or the wireless communications system 100. For example, the carrier bandwidth may be one of a set of bandwidths for carriers of a particular radio access technology (e.g., 1.4, 3, 5, 10, 15, 20, 40, or 80 megahertz (MHz)). Devices of the wireless communications system 100 (e.g., the network entities 105, the UEs 115, or both) may have hardware configurations that support communications using a particular carrier bandwidth or may be configurable to support communications using one of a set of carrier bandwidths. In some examples, the wireless communications system 100 may include network entities 105 or UEs 115 that support concurrent communications using carriers associated with multiple carrier bandwidths. In some examples, each served UE 115 may be configured for operating using portions (e.g., a sub-band, a BWP) or all of a carrier bandwidth.

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

One or more numerologies for a carrier may be supported, and a numerology may include a subcarrier spacing (Δf) and a cyclic prefix. A carrier may be divided into one or more BWPs having the same or different numerologies. In some examples, a UE 115 may be configured with multiple BWPs. In some examples, a single BWP for a carrier may be active at a given time and communications for the UE 115 may be restricted to one or more active BWPs.

The time intervals for the network entities 105 or the UEs 115 may be expressed in multiples of a basic time unit which may, for example, refer to a sampling period of T_{S}=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

A network entity 105 may provide communication coverage via one or more cells, for example a macro cell, a small cell, a hot spot, or other types of cells, or any combination thereof. The term “cell” may refer to a logical communication entity used for communication with a network entity 105 (e.g., using a carrier) and may be associated with an identifier for distinguishing neighboring cells (e.g., a physical cell identifier (PCID), a virtual cell identifier (VCID), or others). In some examples, a cell also may refer to a coverage area 110 or a portion of a coverage area 110 (e.g., a sector) over which the logical communication entity operates. Such cells may range from smaller areas (e.g., a structure, a subset of structure) to larger areas depending on various factors such as the capabilities of the network entity 105. For example, a cell may be or include a building, a subset of a building, or exterior spaces between or overlapping with coverage areas 110, among other examples.

A macro cell generally covers a relatively large geographic area (e.g., several kilometers in radius) and may allow unrestricted access by the UEs 115 with service subscriptions with the network provider supporting the macro cell. A small cell may be associated with a lower-powered network entity 105 (e.g., a lower-powered base station 140), as compared with a macro cell, and a small cell may operate using the same or different (e.g., licensed, unlicensed) frequency bands as macro cells. Small cells may provide unrestricted access to the UEs 115 with service subscriptions with the network provider or may provide restricted access to the UEs 115 having an association with the small cell (e.g., the UEs 115 in a closed subscriber group (CSG), the UEs 115 associated with users in a home or office). A network entity 105 may support one or multiple cells and may also support communications via the one or more cells using one or multiple component carriers.

In some examples, a carrier may support multiple cells, and different cells may be configured according to different protocol types (e.g., MTC, narrowband IoT (NB-IoT), enhanced mobile broadband (eMBB)) that may provide access for different types of devices.

In some examples, a network entity 105 (e.g., a base station 140, an RU 170) may be movable and therefore provide communication coverage for a moving coverage area 110. In some examples, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

Some UEs 115, such as MTC or IoT devices, may be low cost or low complexity devices and may provide for automated communication between machines (e.g., via Machine-to-Machine (M2M) communication). M2M communication or MTC may refer to data communication technologies that allow devices to communicate with one another or a network entity 105 (e.g., a base station 140) without human intervention. In some examples, M2M communication or MTC may include communications from devices that integrate sensors or meters to measure or capture information and relay such information to a central server or application program that uses the information or presents the information to humans interacting with the application program. Some UEs 115 may be designed to collect information or enable automated behavior of machines or other devices. Examples of applications for MTC devices include smart metering, inventory monitoring, water level monitoring, equipment monitoring, healthcare monitoring, wildlife monitoring, weather and geological event monitoring, fleet management and tracking, remote security sensing, physical access control, and transaction-based business charging. In an aspect, techniques disclosed herein may be applicable to MTC or IoT UEs. MTC or IoT UEs may include MTC/enhanced MTC (eMTC, also referred to as CAT-M, Cat M1) UEs, NB-IoT (also referred to as CAT NB1) UEs, as well as other types of UEs. eMTC and NB-IoT may refer to future technologies that may evolve from or may be based on these technologies. For example, eMTC may include FeMTC (further eMTC), eFeMTC (enhanced further eMTC), and mMTC (massive MTC), and NB-IoT may include eNB-IoT (enhanced NB-IoT), and FeNB-IoT (further enhanced NB-IoT).

Some UEs 115 may be configured to employ operating modes that reduce power consumption, such as half-duplex communications (e.g., a mode that supports one-way communication via transmission or reception, but not transmission and reception concurrently). In some examples, half-duplex communications may be performed at a reduced peak rate. Other power conservation techniques for the UEs 115 include entering a power saving deep sleep mode when not engaging in active communications, operating using a limited bandwidth (e.g., according to narrowband communications), or a combination of these techniques. For example, some UEs 115 may be configured for operation using a narrowband protocol type that is associated with a defined portion or range (e.g., set of subcarriers or resource blocks (RBs)) within a carrier, within a guard-band of a carrier, or outside of a carrier.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs 115 via a device-to-device (D2D) communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to each of the other UEs 115 in the group. In some examples, a network entity 105 may facilitate the scheduling of resources for D2D communications. In some other examples, D2D communications may be carried out between the UEs 115 without an involvement of a network entity 105.

In some systems, a D2D communication link 135 may be an example of a communication channel, such as a sidelink communication channel, between vehicles (e.g., UEs 115). In some examples, vehicles may communicate using vehicle-to-everything (V2X) communications, vehicle-to-vehicle (V2V) communications, or some combination of these. A vehicle may signal information related to traffic conditions, signal scheduling, weather, safety, emergencies, or any other information relevant to a V2X system. In some examples, vehicles in a V2X system may communicate with roadside infrastructure, such as roadside units, or with the network via one or more network nodes (e.g., network entities 105, base stations 140, RUs 170) using vehicle-to-network (V2N) communications, or with both.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than 100 kilometers) compared to communications using the smaller frequencies and longer waves of the high frequency (HF) or very high frequency (VHF) portion of the spectrum below 300 MHz.

The wireless communications system 100 may also operate using a super high frequency (SHF) region, which may be in the range of 3 GHz to 30 GHz, also known as the centimeter band, or using an extremely high frequency (EHF) region of the spectrum (e.g., from 30 GHz to 300 GHz), also known as the millimeter band. In some examples, the wireless communications system 100 may support millimeter wave (mmW) communications between the UEs 115 and the network entities 105 (e.g., base stations 140, RUs 170), and EHF antennas of the respective devices may be smaller and more closely spaced than UHF antennas. In some examples, such techniques may facilitate using antenna arrays within a device. The propagation of EHF transmissions, however, may be subject to even greater attenuation and shorter range than SHF or UHF transmissions. The techniques disclosed herein may be employed across transmissions that use one or more different frequency regions, and designated use of bands across these frequency regions may differ by country or regulating body.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

The network entities 105 or the UEs 115 may use MIMO communications to exploit multipath signal propagation and increase spectral efficiency by transmitting or receiving multiple signals via different spatial layers. Such techniques may be referred to as spatial multiplexing. The multiple signals may, for example, be transmitted by the transmitting device via different antennas or different combinations of antennas. Likewise, the multiple signals may be received by the receiving device via different antennas or different combinations of antennas. Each of the multiple signals may be referred to as a separate spatial stream and may carry information associated with the same data stream (e.g., the same codeword) or different data streams (e.g., different codewords). Different spatial layers may be associated with different antenna ports used for channel measurement and reporting. MIMO techniques include single-user MIMO (SU-MIMO), for which multiple spatial layers are transmitted to the same receiving device, and multiple-user MIMO (MU-MIMO), for which multiple spatial layers are transmitted to multiple devices.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The wireless communications system 100 may be a packet-based network that operates according to a layered protocol stack. In the user plane, communications at the bearer or PDCP layer may be IP-based. An RLC layer may perform packet segmentation and reassembly to communicate via logical channels. A MAC layer may perform priority handling and multiplexing of logical channels into transport channels. The MAC layer also may implement error detection techniques, error correction techniques, or both to support retransmissions to improve link efficiency. In the control plane, an RRC layer may provide establishment, configuration, and maintenance of an RRC connection between a UE 115 and a network entity 105 or a core network 130 supporting radio bearers for user plane data. A PHY layer may map transport channels to physical channels.

The devices (e.g., network entities 105 and UEs 115) may support the use of pseudorandom sequences for encoding information bits, such as cell identifiers, UE group identifiers, antenna port indexes, and/or status indications. Such information may be carried in pseudorandom sequences transmitted on downlink, uplink, and/or sidelink signals. Current pseudorandom sequence generation techniques, which may be based on a polynomial structure, may be limited by a small pool size, which may limit the amount of devices or cells. Additionally, current pseudorandom sequence generation techniques may suffer from cross-correlation (e.g., in dual port synchronization signal designs).

Techniques described herein may support an improved pseudorandom sequence generation technique that is based on a coded structure (rather than a polynomial). The described technique may improve auto-correlation and cross-correlation properties, expand the pool size of random sequences, and may support re-use correlation based sequence detection without implementation of a decoder at a receiver device (e.g., a UE 115 or network entity 105). Specifically, the techniques propose the use of an encoder (e.g., error detection/correction encoder) that uses multiple codewords that include information symbols and check symbols. The check symbols may be cyclic redundancy check (CRC) symbols of an error detection codebook or parity check symbols of the error correction codebook. Further, the described techniques support multi-stage randomization and OCC techniques for further pseudorandom code improvement.

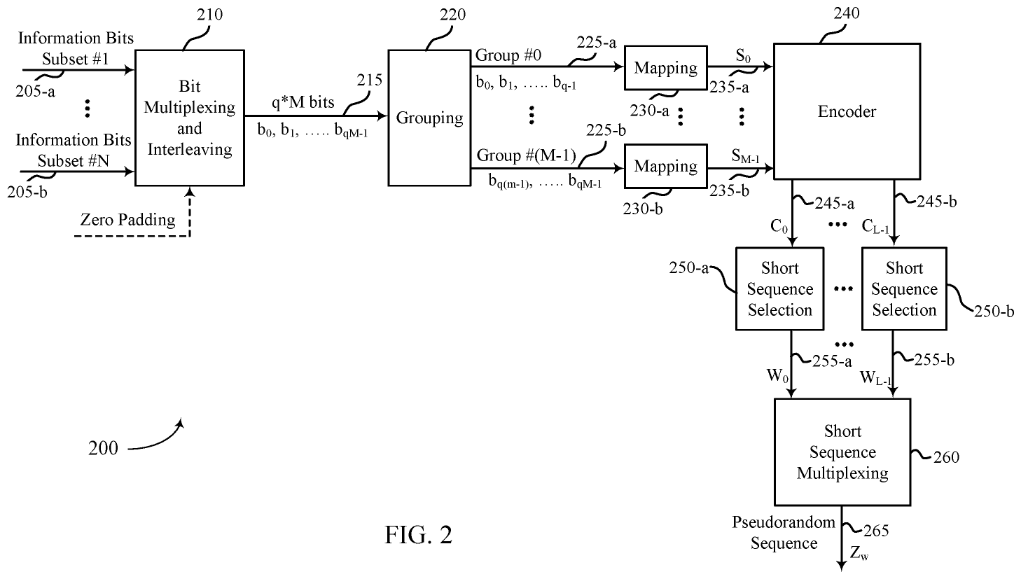

FIG. 2 illustrates an example of a procedure 200 that supports generation of coded pseudorandom sequences in accordance with one or more aspects of the present disclosure. The procedure 200 may be implemented by a network entity 105 and/or a UE 115 as described with respect to FIG. 1. For example, a UE 115 may encode information bits (e.g., a UE group identifier) into a pseudorandom sequence that is generated in accordance with the procedure 200, and the pseudorandom sequence encoding the information bits may be transmitted to a network entity 105 or another UE 115.

At 210, a plurality of subsets (e.g., subsets 205, including subset 205-a through subset 205-b) of information bits may be processed. In some cases, a sequence of information bits is divided into the plurality of subsets, such as N subsets. For example, the procedure 200 may be used to generate a binary or non-binary pseudo random sequence carrying K information bits (1≤K≤q*M) from N subsets (N≥1). In an example, a cell ID may be in subset #1, antenna port index in subset #2, and so forth. Each subset of information bits may correspond to an information symbol, such as information corresponding to a cell identifier, antenna port index, UE group identifier, or a status indication field. It should be understood that other types of encodable information are contemplated within the scope of the present disclosure. The information, as well as configurations (e.g., error rate, coding rate, quantity of sequences, quantity of groups) may depend on the type of information being set. The processing may include bit multiplexing and/or interleaving of the information bits which may result in a bit sequence 215 of information bits (e.g., q*M bits). Depending on the coding structure, the subsets of information bits (e.g., subsets 205) may be zero-padded before multiplexing and/or interleaving. For example, zero-padding may be used to ensure that the segments of bit groups include an equal quantity of bits, q. The q*M bits (e.g., the quantity of bits) may be indexed as b₀, b₁, . . . b_{qM-1}.

At 220, the bit sequence 215 of information bits may be segmented into a set of bit groups (e.g., bit group 225-a and bit group 225-b), with a total of M groups. Each bit group may have an equal quantity of bits, q, such that a total quantity of bits across the groups is q*M. At 230 (e.g., at 230-a through 230-b), each group 225 of size q is mapped to an information symbol 235 (e.g., including an information symbol 235-a through an information symbol 235-b), such that a set of ordered information symbols is generated. Each information symbol of the set of ordered information symbol corresponds to a group 225. The symbols may be non-binary (e.g., complex) and may correspond to different amplitudes and/or phases of a waveform.

The information symbols 235 are input into an encoder 240, which may add parity symbols and/or CRC symbols. The encoder 240 may be an error detection encoder or an error correction encoder. The error detection encoder may add CRC symbols, and the error correction encoder may add parity bits. The encoder 240 may use a codebook of error detection/correction codes that include multiple codewords. Each information symbol 235 may be mapped to a codeword including both information symbols and check symbols (e.g., CRC symbols). In some examples, the information symbols 235 are first encoded to an error detection codeword A, and the codeword A is further encoded into an error correction codeword A′. The codebook used by the encoder 240 may be selected from the family of maximum distance separate codes such as the Reed-Solomon code or Bose-Chaudhuri-Hocquenghem code such as to improve correlation properties of the produced pseudorandom sequence. Using the distance separate codes may reduce or minimize the cross-correlation of pseudorandom sequences. The encoder 240 may generate L-M parity symbols for M information symbols. M symbols may be input into the encoder 240, and the encoder may add additional symbols (e.g., parity symbols) resulting in L symbols, where symbols L-M are the parity symbols.

Each encoded symbol 245 (e.g., codeword, including encoded symbols 245-a through 245-b) output by the encoder 240 is demapped at 250 (e.g., at 250-a through 250-b) to generate a plurality of sequences (e.g., sequence 255, such as sequences 255-a through 255-b). The demapping at 250 may result in L sequences 255. Each short sequence Wₗ may be mapped to a symbol Cₗ, where 0≤l<L. The L symbols {Cₗ, 0≤l<L} may be generated by an encoder 240 defined on a finite field with 2q elements (q≥1). The sequences 255 may be binary or non-binary. These short sequences 255 resulting from the mapping at 250 are concatenated and/or multiplexed at 260 to produce pseudorandom sequence 265 (e.g., Z_{w}). The short sequences 255 may be channel symbols or modulation symbols. The demapping technique at 250 may be reverse of the technique for mapping at 230. The pseudorandom sequence 265 may be binary or complex. The pseudorandom sequence 265 may be constructed by multiplexing or concatenating L short sequences indexed by W₀, W₁, . . . W_{L-1}.

In some cases, a device, such as a UE 115, may receive signaling that indicates a configuration for performing the procedure 200. The configuration may indicate the code/algorithm used by the encoder, a coding rate, the mapping or demapping technique, quantity of sequences or groups, or a combination thereof. Further, as described herein, multi-stage randomization may be used, in addition to the procedure 200, as well as OCC techniques. In some examples (e.g., in uplink examples), configurations for pseudorandom sequence generation may be included in system information signaling.

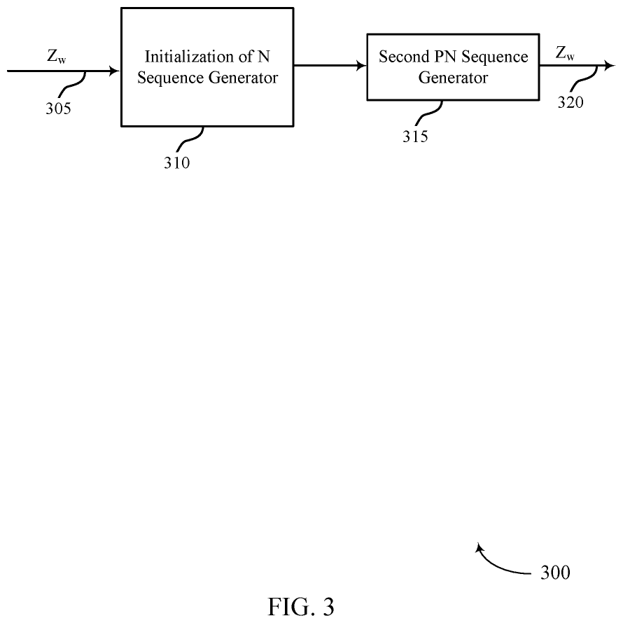

FIG. 3 illustrates an example of a multi-stage randomization procedure 300 that supports generation of coded pseudorandom sequences in accordance with one or more aspects of the present disclosure. The multi-stage randomization procedure 300 may be implemented by a network entity 105 and/or a UE 115 as described with respect to FIG. 1. For example, a UE 115 may encode information bits (e.g., a UE group identifier) into a pseudorandom sequence that is generated in accordance with the multi-stage randomization procedure 300, and the pseudorandom sequence encoding the information bits may be transmitted to a network entity 105 or another UE 115.

To further reduce cross-correlation between pseudorandom sequences generated (e.g., via procedure 200 of FIG. 2), an output pseudorandom sequence may be used to initialize a second pseudorandom sequence generator 315. The second pseudorandom sequence generator 315 may implement the procedure 200 as described with respect to FIG. 2, or may use a different algorithm/technique, such as linear-feedback shift register(s). Linear-feedback shift registers may be examples of the registers as used by an m-sequence technique or a Gold sequence technique.

For example, a pseudo random sequence Z_{w,0} (non-binary or binary) that is output from the procedure 200 of FIG. 2 (or via another procedure), may be used to initialize, at 310, the linear-feedback shift registers. For example, initialization at 310 may be based on the value of the input pseudorandom sequence 305. Additionally, or alternatively, the pseudo random sequence Z_{w,0} that is output from the procedure 200 of FIG. 2 may be used as the information bits/symbols of the error detection/correction codeword associated with the second pseudorandom sequence generator 315, which may also implement the procedure 200 of FIG. 2 (or a similar technique with different configurations). The second pseudorandom sequence generator 315 (e.g., implementing procedure 200 or another procedure) may output a second pseudorandom sequence 320, which may be longer than the input pseudorandom sequence 305.

As multi-stage randomization may support an increase in length of a pseudorandom sequence, the multi-stage randomization procedure 300 may support reduction of inter-cell interference or intra-cell interference. In some examples, control signaling may be used to indicate a configuration for multi-stage randomization. The configuration may include whether multi-stage randomization is enabled or other parameters (e.g., an initialization formula, timing information) for the second pseudorandom sequence generator 315.

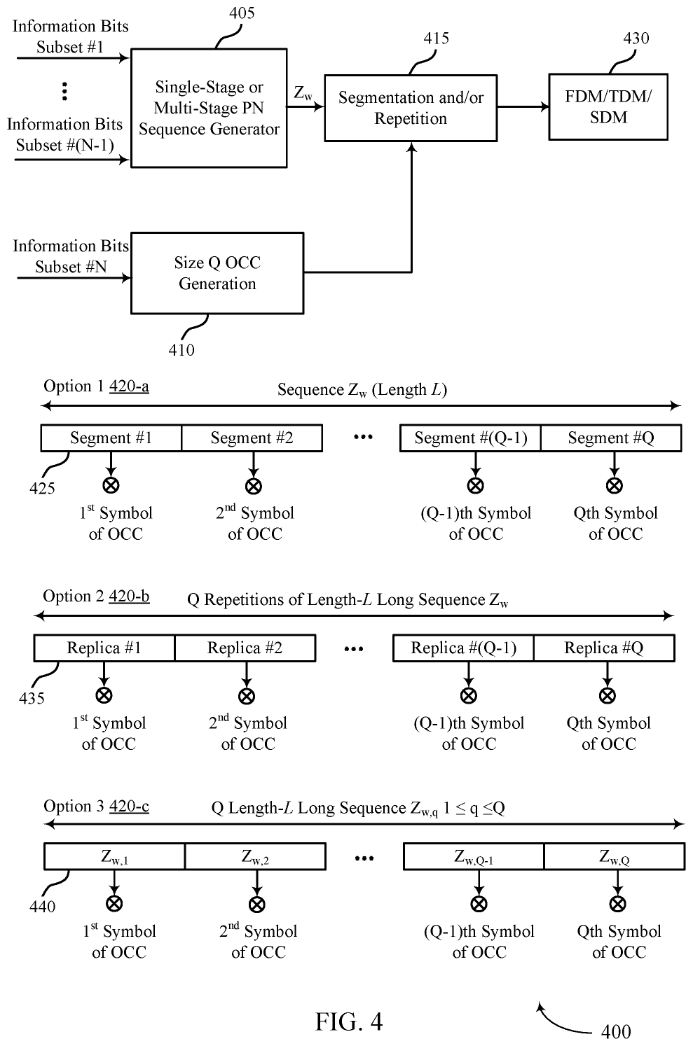

FIG. 4 illustrates an example of an OCC procedure 400 that supports generation of coded pseudorandom sequences in accordance with one or more aspects of the present disclosure. The OCC procedure 400 may be implemented by a network entity 105 and/or a UE 115 as described with respect to FIG. 1. For example, a UE 115 may encode information bits (e.g., a UE group identifier) into a pseudorandom sequence that is generated in accordance with the OCC procedure 400, and the pseudorandom sequence encoding the information bits may be transmitted to a network entity 105 or another UE 115. The OCC procedure 400 may be used in MIMO environments, where a device (e.g., UE 115 or network entity 105) differentiates between antenna ports (e.g., dual port synchronization signal designs). The OCC procedure 400 may be used to generate orthogonal or pseudo-orthogonal sequences.

A pseudorandom sequence generator 405 may receive input information bits and generate a pseudorandom sequence that encodes the information bits. The pseudorandom sequence generator 405 may be an example of a single-stage pseudorandom sequence generator (e.g., a generator the implements procedure 200 of FIG. 2) or a multi-stage pseudorandom sequence generator (e.g., a generator that implements multi-stage randomization procedure 300 of FIG. 3). The output pseudorandom sequence may have a length L.

A subset of the information bits that are input into the pseudorandom generator may be used to select or generate an OCC at 410. The information bits in the Nth subset (e.g., where N>1) may include time information, frequency information, space information, a cell identifier, a UE identifier, a group identifier, or any combination thereof. The OCC may be generated based on a closed-form formula, such as Walsh-Hadamard code, constant amplitude zero autocorrelation waveform sequence, a chirp sequence, a lookup table, or any combination thereof. The OCC may have a size of Q, which may be odd or even integers greater than or equal to two. The symbols of the OCC may be binary or non-binary, real or complex.

After generation of the OCC based on a segment of the information bits (e.g., segment N), the generated OCC may be applied to a segmented or repeated version of the pseudorandom sequence Z_{w}. Various options 420 may be used to apply the OCC to the pseudorandom sequence. According to a first option 420-a, the pseudorandom sequence, Z_{w}, is partitioned, at 415, into Q non-overlapping segments (e.g., segment 425), and the q-th segment of the pseudorandom sequence is multiplied by the q-th symbol of the OCC to generate a plurality of orthogonal or pseudo-orthogonal random sequences. For example, the first segment 425 is multiplied by the first symbol of the OCC to generate a first orthogonal or pseudo-orthogonal sequence. The plurality of orthogonal or pseudo-orthogonal random sequences may be multiplexed at 430 (e.g., frequency domain multiplexed (FDM), time domain multiplexed (TDM), or spatial domain multiplexed (SD_{M})) and used to generate and/or transmit one or more reference signals.

According to a second option 420-b, the pseudorandom sequence, Z_{w}, is repeated, at 415, to produce Q replicas (e.g., replica 435), and the q-th replica is multiplied by the q-th symbol of the OCC to generate a plurality of orthogonal or pseudo-orthogonal random sequences. For example, the first replica 435 is multiplied by the first symbol of the OCC to generate a first orthogonal or pseudo-orthogonal sequence. The orthogonal or pseudo-orthogonal sequences may be concatenated to produce a longer sequence of length L*Q.

According to a third option 420-c, Q different random sequences Z_{W1}, Z_{W2}, . . . Z_{WQ} are ordered as Z_{W1}, Z_{W2}, . . . Z_{WQ}, and are each multiplied by an OCC symbol (e.g., Z_{wq} is multiplied by the q-th symbol of the OCC) to produce a plurality of orthogonal or pseudo-orthogonal random sequences. For example, the pseudorandom sequence 440 is multiplied by the first symbol of the OCC to generate a first orthogonal or pseudo-orthogonal sequence. The orthogonal or pseudo-orthogonal sequences may be concatenated to produce a longer sequence of length L*Q, where 1≤q≤Q. As such, the various OCC procedure options 420 may be used in conjunction with procedure 200 and multi-stage randomization procedure 300 to produce orthogonal sequences, which may further enhance wireless communications.

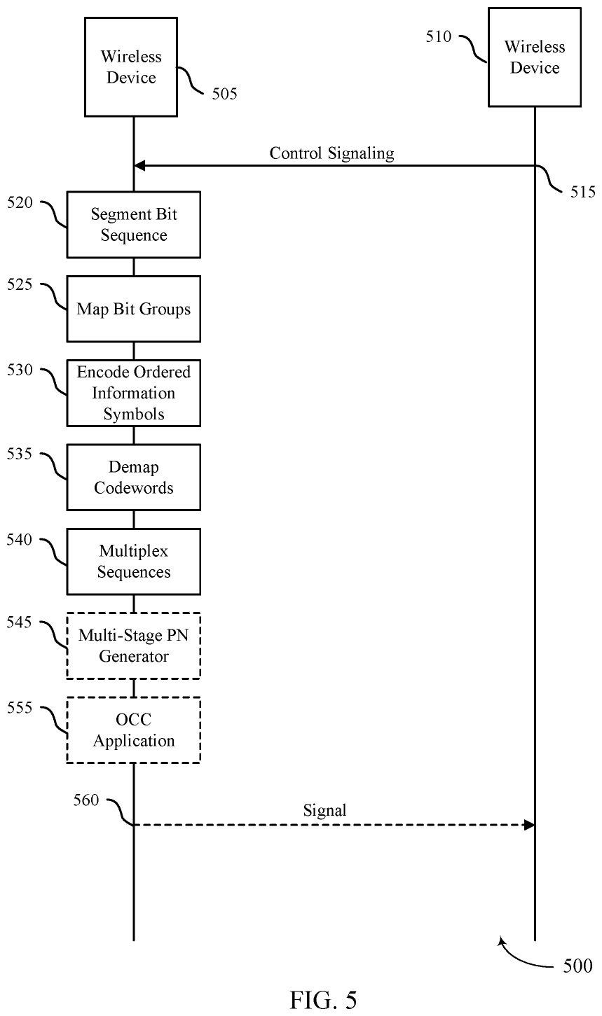

FIG. 5 illustrates an example of a process flow 500 that supports generation of coded pseudorandom sequences in accordance with one or more aspects of the present disclosure. The process flow 500 includes a wireless device 505 and a wireless device 510. The wireless devices 505 and 510 may be examples of a UE 115 and/or a network entity 105, as described with respect to FIG. 1. The process flow 500 may implement aspects of procedure 200, multi-stage randomization procedure 300, and OCC procedure 400 as described with respect to FIGS. 1 through 4. In some examples, some signaling or procedure of the process flow 500 may occur in different orders than shown. Additionally, or alternatively, some additional procedures of signaling may occur, or some signaling or procedures may not occur.

At 515, the wireless device 505 may receive, from the wireless device 510, control signaling that indicates a configuration for generating a pseudorandom sequence. The configuration may specify whether the wireless device 505 is to use single-stage randomization or multi-stage randomization, whether the wireless device 505 is to use an OCC, and/or pseudorandom sequence generation technique parameters, such as a quantity of segments or the coding rate.

At 520, the wireless device 505 may segment a bit sequence of information bits into a plurality of bit groups. The segment of information bits may include multiplexed and/or interleaved bits from a multiple subsets of information bits, each of which may correspond to an information field or symbol (e.g., defined on a finite field). In some examples, the subsets may be zero-padded. The zero-padding may be performed in order to define fixed length for grouping subsets.

At 525, the wireless device 505 may map each bit group of the plurality of bit groups to a respective symbol to generate a plurality of ordered information symbols. At 530, the wireless device may encode the ordered information symbols to generate a plurality of codewords. The encoding may include encoding the information symbols using a codebook (e.g., pre-configured) associated with an error detection code or an error correction code. The codewords may be generated to include information symbols of the plurality of ordered information symbols and check symbols. The check symbols may include CRC symbols of the error detection code and/or parity check symbols of the error correction code. The codewords of the codebook may have defined separate distance (e.g., maximum separate distance) for a given code rate or a given codebook size. The codewords may be generated using an error correction algorithm that is a Reed-Solomon code or a Bose-Chaudhuri-Hocquenghem code. Other codeword generation algorithms are contemplated within the scope of the present disclosure.

At 535, the wireless device 505 may demap each codeword of the plurality of codewords to generate a plurality of sequences. At 540, the wireless device 505 may multiplex (e.g., concatenate) the plurality of sequence to generate a pseudorandom sequence. The generated pseudorandom sequence may be binary or non-binary.

At 545, the wireless device 505 may use a multi-stage pseudorandom sequence generator. For example, the wireless device 505 may initialize a second sequence pseudorandom sequence generator using the pseudorandom sequence generated at 540. Further, the pseudorandom sequence generated at 540 may be input into the second pseudorandom sequence generator. In some examples, the second pseudorandom sequence generator is an example of one or more linear-feedback shift registers that are defined on a binary finite field or a non-binary finite field. In other examples, the second pseudorandom sequence generator implements the techniques described at 520 through 540 where the pseudorandom sequence (that is coded and includes information symbols and check symbols) is input into the second pseudorandom sequence generator.

At 555, the wireless device 505 may apply an OCC to the generated pseudorandom sequence (e.g., output from a single-stage or multi-stage implementation). Application of the OCC may include generating a plurality of bit subsets based on ordered information bits and generating an OCC based on a first subset of the plurality of subsets of information bits. The pseudorandom sequence may be segmented, replicated, or combined with other pseudorandom sequences. The generated OCC may be applied to the segment pseudorandom sequence, replicated, or grouping of pseudorandom sequences to generate a plurality of orthogonal or pseudo-orthogonal random sequences. For example, the pseudorandom sequence is segmented into a plurality of pseudorandom symbol subsets, and a pseudorandom symbol subset is multiplied by a respective symbol of the OCC. In another example, the pseudorandom sequence is replicated to generate a plurality of pseudorandom symbol subsets, and a pseudorandom symbol subset is multiplied by a respective symbol of the OCC. In another example, the pseudorandom sequence is combined with other pseudorandom sequences to generate a plurality of pseudorandom symbol subsets, and a pseudorandom symbol subset is multiplied by a respective symbol of the OCC. The application of the OCC to the pseudorandom symbol subsets may result in a plurality of orthogonal or pseudo-orthogonal random sequences. The plurality of orthogonal or pseudo-orthogonal random sequences may be used to generate a reference signal that is transmitted at 560. In other cases, the generated reference signal is used to correlate with a downlink signal for receiving.

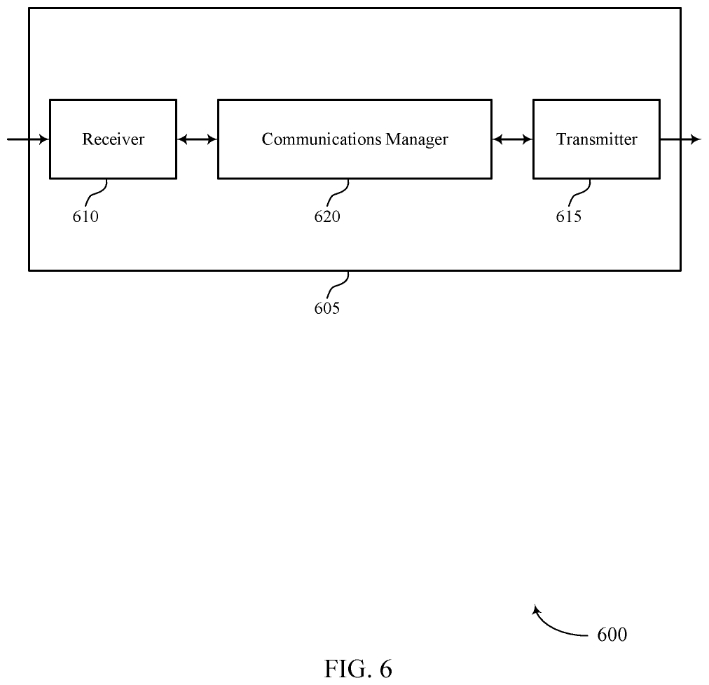

FIG. 6 shows a block diagram 600 of a device 605 that supports generation of coded pseudorandom sequences in accordance with one or more aspects of the present disclosure. The device 605 may be an example of aspects of a UE 115 or a network entity 105 as described herein. The device 605 may include a receiver 610, a transmitter 615, and a communications manager 620. The device 605 may also include a processor. Each of these components may be in communication with one another (e.g., via one or more buses).

The receiver 610 may provide a means for receiving information such as packets, user data, control information, or any combination thereof associated with various information channels (e.g., control channels, data channels, information channels related to generation of coded pseudorandom sequences). Information may be passed on to other components of the device 605. The receiver 610 may utilize a single antenna or a set of multiple antennas.

The transmitter 615 may provide a means for transmitting signals generated by other components of the device 605. For example, the transmitter 615 may transmit information such as packets, user data, control information, or any combination thereof associated with various information channels (e.g., control channels, data channels, information channels related to generation of coded pseudorandom sequences). In some examples, the transmitter 615 may be co-located with a receiver 610 in a transceiver module. The transmitter 615 may utilize a single antenna or a set of multiple antennas.

The communications manager 620, the receiver 610, the transmitter 615, or various combinations thereof or various components thereof may be examples of means for performing various aspects of generation of coded pseudorandom sequences as described herein. For example, the communications manager 620, the receiver 610, the transmitter 615, or various combinations or components thereof may support a method for performing one or more of the functions described herein.

In some examples, the communications manager 620, the receiver 610, the transmitter 615, or various combinations or components thereof may be implemented in hardware (e.g., in communications management circuitry). The hardware may include a processor, a digital signal processor (DSP), a central processing unit (CPU), graphics processor unit (GPU), an application-specific integrated circuit (ASIC), a field-programmable gate array (FPGA) or other programmable logic device, a microcontroller, discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally, or alternatively, in some examples, the communications manager 620, the receiver 610, the transmitter 615, or various combinations or components thereof may be implemented in code (e.g., as communications management software) executed by a processor. If implemented in code executed by a processor, the functions of the communications manager 620, the receiver 610, the transmitter 615, or various combinations or components thereof may be performed by a general-purpose processor, a DSP, a CPU, a GPU, an ASIC, an FPGA, a microcontroller, or any combination of these or other programmable logic devices (e.g., configured as or otherwise supporting a means for performing the functions described in the present disclosure).

In some examples, the communications manager 620 may be configured to perform various operations (e.g., receiving, obtaining, monitoring, outputting, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to obtain information, output information, or perform various other operations as described herein.

The communications manager 620 may support wireless communication at a wireless device in accordance with examples as disclosed herein. For example, the communications manager 620 may be configured as or otherwise support a means for segmenting a bit sequence of information bits into a set of multiple bit groups. The communications manager 620 may be configured as or otherwise support a means for mapping each bit group of the set of multiple bit groups to a respective symbol to generating a set of multiple ordered information symbols. The communications manager 620 may be configured as or otherwise support a means for encoding the set of multiple ordered information symbols to generate a set of multiple codewords. The communications manager 620 may be configured as or otherwise support a means for demapping each codeword of the set of multiple codewords to generate a set of multiple sequences. The communications manager 620 may be configured as or otherwise support a means for multiplexing the set of multiple sequences to generate a pseudorandom sequence. The communications manager 620 may be configured as or otherwise support a means for transmitting a signal generated based on the pseudorandom sequence.

Additionally, or alternatively, the communications manager 620 may support wireless communication at a wireless device in accordance with examples as disclosed herein. For example, the communications manager 620 may be configured as or otherwise support a means for generating a set of multiple bit subsets based on a set of multiple ordered information bits. The communications manager 620 may be configured as or otherwise support a means for generating an OCC based on a first subset of the set of multiple bit subsets. The communications manager 620 may be configured as or otherwise support a means for applying the OCC to an input pseudorandom sequence to generate a set of multiple orthogonal or pseudo-orthogonal random sequences. The communications manager 620 may be configured as or otherwise support a means for generating a reference signal based on the set of multiple orthogonal or pseudo-orthogonal random sequences.

By including or configuring the communications manager 620 in accordance with examples as described herein, the device 605 (e.g., a processor controlling or otherwise coupled with the receiver 610, the transmitter 615, the communications manager 620, or a combination thereof) may support techniques for encoded pseudorandom number generation that results in more efficient utilization of communication resources by reducing cross-correlation, thereby improving communication efficiency.

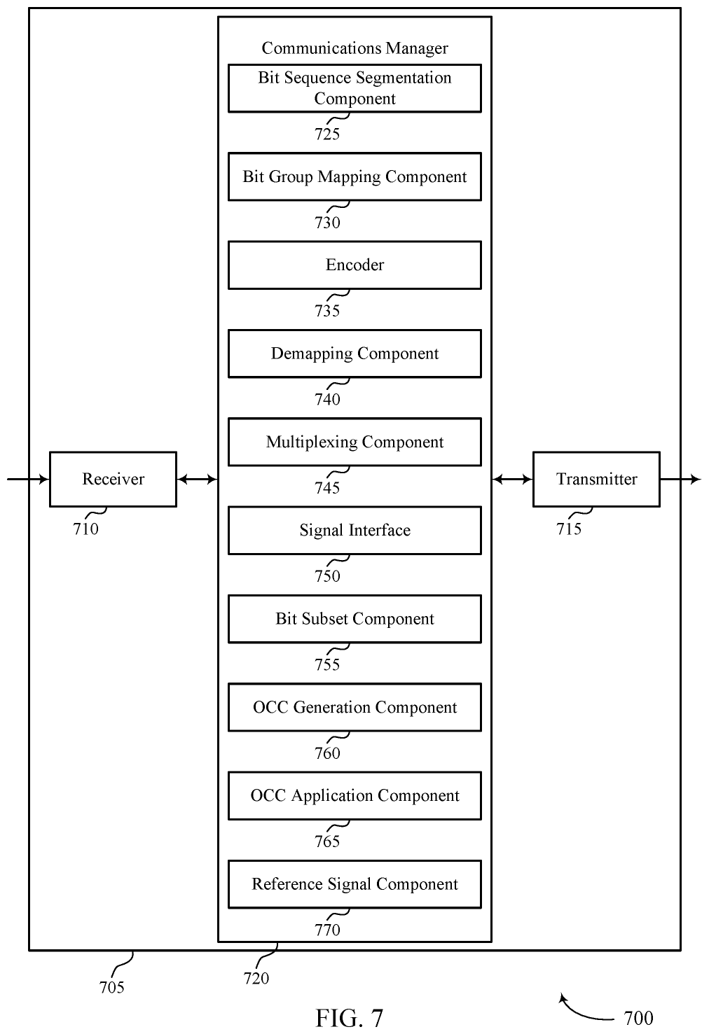

FIG. 7 shows a block diagram 700 of a device 705 that supports generation of coded pseudorandom sequences in accordance with one or more aspects of the present disclosure. The device 705 may be an example of aspects of a device 605, a UE 115, or a network entity 105 as described herein. The device 705 may include a receiver 710, a transmitter 715, and a communications manager 720. The device 705 may also include a processor. Each of these components may be in communication with one another (e.g., via one or more buses).

The receiver 710 may provide a means for receiving information such as packets, user data, control information, or any combination thereof associated with various information channels (e.g., control channels, data channels, information channels related to generation of coded pseudorandom sequences). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (e.g., control channels, data channels, information channels related to generation of coded pseudorandom sequences). In some examples, the transmitter 715 may be co-located with a receiver 710 in a transceiver module. The transmitter 715 may utilize a single antenna or a set of multiple antennas.

The device 705, or various components thereof, may be an example of means for performing various aspects of generation of coded pseudorandom sequences as described herein. For example, the communications manager 720 may include a bit sequence segmentation component 725, a bit group mapping component 730, an encoder 735, a demapping component 740, a multiplexing component 745, a signal interface 750, a bit subset component 755, a OCC generation component 760, a OCC application component 765, a reference signal component 770, or any combination thereof. The communications manager 720 may be an example of aspects of a communications manager 620 as described herein. In some examples, the communications manager 720, or various components thereof, may be configured to perform various operations (e.g., receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communication at a wireless device in accordance with examples as disclosed herein. The bit sequence segmentation component 725 may be configured as or otherwise support a means for segmenting a bit sequence of information bits into a set of multiple bit groups. The bit group mapping component 730 may be configured as or otherwise support a means for mapping each bit group of the set of multiple bit groups to a respective symbol to generate a set of multiple ordered information symbols. The encoder 735 may be configured as or otherwise support a means for encoding the set of multiple ordered information symbols to generate a set of multiple codewords. The demapping component 740 may be configured as or otherwise support a means for demapping each codeword of the set of multiple codewords to generate a set of multiple sequences. The multiplexing component 745 may be configured as or otherwise support a means for multiplexing the set of multiple sequences to generate a pseudorandom sequence. The signal interface 750 may be configured as or otherwise support a means for transmitting a signal generated based on the pseudorandom sequence.

Additionally, or alternatively, the communications manager 720 may support wireless communication at a wireless device in accordance with examples as disclosed herein. The bit subset component 755 may be configured as or otherwise support a means for generating a set of multiple bit subsets based on a set of multiple ordered information bits. The OCC generation component 760 may be configured as or otherwise support a means for generating an OCC based on a first subset of the set of multiple bit subsets. The OCC application component 765 may be configured as or otherwise support a means for applying the OCC to an input pseudorandom sequence to generate a set of multiple orthogonal or pseudo-orthogonal random sequences. The reference signal component 770 may be configured as or otherwise support a means for generating a reference signal based on the set of multiple orthogonal or pseudo-orthogonal random sequences.

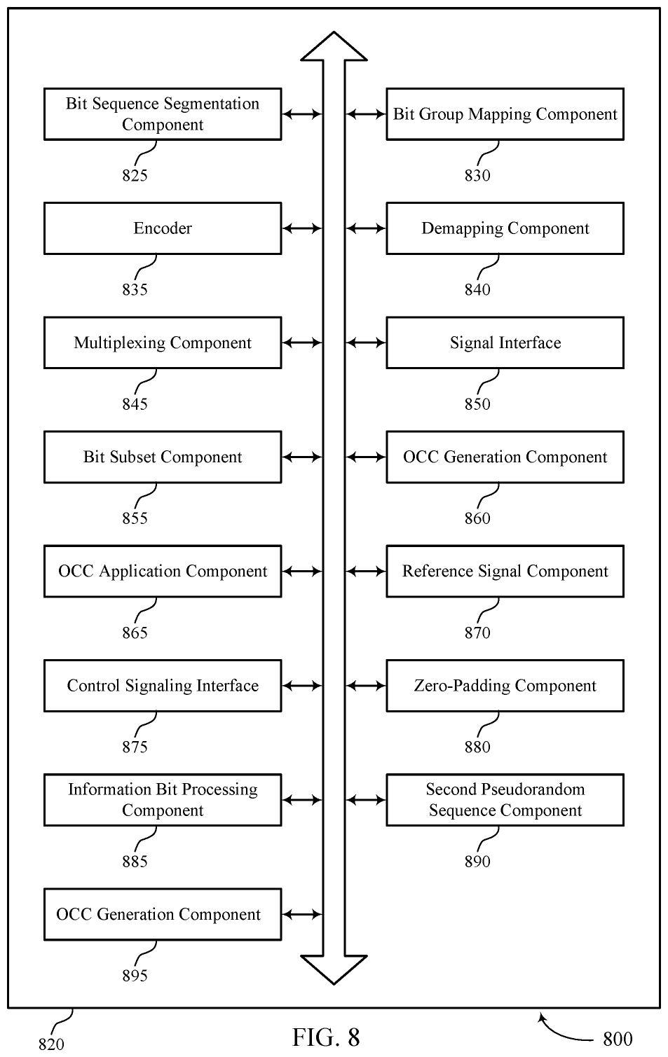

FIG. 8 shows a block diagram 800 of a communications manager 820 that supports generation of coded pseudorandom sequences in accordance with one or more aspects of the present disclosure. The communications manager 820 may be an example of aspects of a communications manager 620, a communications manager 720, or both, as described herein. The communications manager 820, or various components thereof, may be an example of means for performing various aspects of generation of coded pseudorandom sequences as described herein. For example, the communications manager 820 may include a bit sequence segmentation component 825, a bit group mapping component 830, an encoder 835, a demapping component 840, a multiplexing component 845, a signal interface 850, a bit subset component 855, a OCC generation component 860, a OCC application component 865, a reference signal component 870, a control signaling interface 875, a zero-padding component 880, an information bit processing component 885, a second pseudorandom sequence component 890, a OCC generation component 895, or any combination thereof. Each of these components may communicate, directly or indirectly, with one another (e.g., via one or more buses) which may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 820 may support wireless communication at a wireless device in accordance with examples as disclosed herein. The bit sequence segmentation component 825 may be configured as or otherwise support a means for segmenting a bit sequence of information bits into a set of multiple bit groups. The bit group mapping component 830 may be configured as or otherwise support a means for mapping each bit group of the set of multiple bit groups to a respective symbol to generate a set of multiple ordered information symbols. The encoder 835 may be configured as or otherwise support a means for encoding the set of multiple ordered information symbols to generate a set of multiple codewords. The demapping component 840 may be configured as or otherwise support a means for demapping each codeword of the set of multiple codewords to generate a set of multiple sequences. The multiplexing component 845 may be configured as or otherwise support a means for multiplexing the set of multiple sequences to generate a pseudorandom sequence. The signal interface 850 may be configured as or otherwise support a means for transmitting a signal generated based on the pseudorandom sequence.

In some examples, the control signaling interface 875 may be configured as or otherwise support a means for receiving control signaling that indicates that the wireless device is to use single-stage randomization or multi-stage randomization, where the pseudorandom sequence is generated based on multi-stage randomization.

In some examples, the control signaling interface 875 may be configured as or otherwise support a means for receiving control signaling that indicates that the wireless device is to use an OCC to generate a set of multiple orthogonal sequences based on the pseudorandom sequence, where the signal is generated based on the OCC.

In some examples, the control signaling interface 875 may be configured as or otherwise support a means for receiving control signaling that indicates a configuration for generating the pseudorandom sequence, where pseudorandom sequence is generated based on the configuration.

In some examples, to support encoding the set of multiple ordered information symbols, the encoder 835 may be configured as or otherwise support a means for encoding the set of multiple ordered information symbols using a codebook associated with an error detection code or an error correction code. In some examples, to support encoding the set of multiple ordered information symbols, the encoder 835 may be configured as or otherwise support a means for generating a codeword including information symbols of the set of multiple ordered information symbols and a set of multiple check symbols, where the check symbols include CRC symbols of the error detection code, parity check symbols of the error correction code, or a combination thereof.

In some examples, codewords in the codebook have a defined separation distance for a given code rate or a given codebook size.

In some examples, the codeword is generated using an error detection coding algorithm that is a Reed-Solomon code or a Bose-Chaudhuri-Hocquenghem code.

In some examples, the zero-padding component 880 may be configured as or otherwise support a means for zero-padding each subset of information bits of a set of multiple subsets of information bits, each subset of information bits corresponding to an information symbol defined on a finite field, where the zero-padding results in the bit sequence of information bits.

In some examples, the information bit processing component 885 may be configured as or otherwise support a means for processing a set of multiple subsets of information bits, each subset of information bits corresponding to an information symbol, the processing including multiplexing, interleaving, or both the set of multiple subsets of information bits resulting in the set of multiple ordered information symbols.

In some examples, the second pseudorandom sequence component 890 may be configured as or otherwise support a means for initializing a second pseudorandom sequence generator based on the pseudorandom sequence, where elements of the pseudorandom sequence are binary or non-binary.

In some examples, the second pseudorandom sequence generator includes one or more linear-feedback shift registers and. In some examples, operation of the one or more linear-feedback shift registers is defined on a binary finite field or a non-binary finite field.

In some examples, to support initializing the second pseudorandom sequence generator, the second pseudorandom sequence component 890 may be configured as or otherwise support a means for using the pseudorandom sequence that is coded and includes a set of multiple information symbols and check symbols as input into the initialized second pseudorandom sequence generator.

In some examples, the bit subset component 855 may be configured as or otherwise support a means for generating a set of multiple bit subsets based on a set of multiple ordered information bits. In some examples, the OCC generation component 895 may be configured as or otherwise support a means for generating an OCC based on a first subset of the set of multiple bit subsets. In some examples, the OCC application component 865 may be configured as or otherwise support a means for applying the OCC to the pseudorandom sequence to generate a set of multiple orthogonal or pseudo-orthogonal random sequences. In some examples, the reference signal component 870 may be configured as or otherwise support a means for generating a reference signal based on the set of multiple orthogonal or pseudo-orthogonal random sequences.

In some examples, the multiplexing component 845 may be configured as or otherwise support a means for multiplexing the set of multiple orthogonal or pseudo-orthogonal random sequences to generate a multiplexed signal, where the reference signal is generated based on the multiplexed set of multiple orthogonal or pseudo-orthogonal random sequences.

In some examples, to support generating the OCC, the OCC generation component 860 may be configured as or otherwise support a means for generating the OCC using a closed-form formula including a Walsh-Hadamard code, a constant amplitude zero autocorrelation waveform sequence, a chirp sequence, or any combination thereof.

In some examples, to support applying the OCC, the OCC application component 865 may be configured as or otherwise support a means for multiplying each pseudorandom symbol subset of a set of multiple pseudorandom symbol subsets by a respective symbol of the OCC to generate the set of multiple orthogonal or pseudo-orthogonal random sequences, where the pseudorandom sequence is segmented to generate the set of multiple pseudorandom symbol subsets.

In some examples, to support applying the OCC, the OCC application component 865 may be configured as or otherwise support a means for multiplying each pseudorandom symbol subset of a set of multiple pseudorandom symbol subsets by a respective symbol of the OCC to generate the set of multiple orthogonal or pseudo-orthogonal random sequences, where the pseudorandom sequence is repeated to generate the set of multiple pseudorandom symbol subsets.

In some examples, to support applying the OCC, the OCC application component 865 may be configured as or otherwise support a means for multiplying each pseudorandom symbol subset of a set of multiple pseudorandom symbol subsets by a respective symbol of the OCC to generate the set of multiple orthogonal or pseudo-orthogonal random sequences, where the pseudorandom sequence is concatenated with one or more second pseudorandom sequences to generate the set of multiple pseudorandom symbol subsets.

Additionally, or alternatively, the communications manager 820 may support wireless communication at a wireless device in accordance with examples as disclosed herein. The bit subset component 855 may be configured as or otherwise support a means for generating a set of multiple bit subsets based on a set of multiple ordered information bits. The OCC generation component 860 may be configured as or otherwise support a means for generating an OCC based on a first subset of the set of multiple bit subsets. The OCC application component 865 may be configured as or otherwise support a means for applying the OCC to an input pseudorandom sequence to generate a set of multiple orthogonal or pseudo-orthogonal random sequences. The reference signal component 870 may be configured as or otherwise support a means for generating a reference signal based on the set of multiple orthogonal or pseudo-orthogonal random sequences.

In some examples, the multiplexing component 845 may be configured as or otherwise support a means for multiplexing the set of multiple orthogonal or pseudo-orthogonal random sequences to generate a multiplexed signal, where the reference signal is generated based on the multiplexed set of multiple orthogonal or pseudo-orthogonal random sequences.

In some examples, to support generating the OCC, the OCC generation component 860 may be configured as or otherwise support a means for generating the OCC using a closed-form formula that is a Walsh-Hadamard code, or a constant amplitude zero autocorrelation waveform sequence, or a chirp sequence, or any combination thereof.

In some examples, to support applying the OCC, the OCC application component 865 may be configured as or otherwise support a means for multiplying each pseudorandom symbol subset of a set of multiple pseudorandom symbol subsets by a respective symbol of the OCC to generate the set of multiple orthogonal or pseudo-orthogonal random sequences, where the input pseudorandom sequence is segmented to generate the set of multiple pseudorandom symbol subsets.

In some examples, to support applying the OCC, the OCC application component 865 may be configured as or otherwise support a means for multiplying each pseudorandom symbol subset of a set of multiple pseudorandom symbol subsets by a respective symbol of the OCC to generate the set of multiple orthogonal or pseudo-orthogonal random sequences, where the input pseudorandom sequence is repeated to generate the set of multiple pseudorandom symbol subsets.

In some examples, to support applying the OCC, the OCC application component 865 may be configured as or otherwise support a means for multiplying each pseudorandom symbol subset of a set of multiple pseudorandom symbol subsets by a respective symbol of the OCC to generate the set of multiple orthogonal or pseudo-orthogonal random sequences, where the input pseudorandom sequence is concatenated with one or more second pseudorandom sequences to generate the set of multiple pseudorandom symbol subsets.

In some examples, the bit sequence segmentation component 825 may be configured as or otherwise support a means for segmenting a bit sequence of information bits into a set of multiple bit groups. In some examples, the bit group mapping component 830 may be configured as or otherwise support a means for mapping each bit group of the set of multiple bit groups to a respective symbol to generate a set of multiple ordered information symbols. In some examples, the encoder 835 may be configured as or otherwise support a means for encoding the set of multiple ordered information symbols to generate a set of multiple codewords. In some examples, the demapping component 840 may be configured as or otherwise support a means for demapping each codeword of the set of multiple codewords to generate a set of multiple sequences. In some examples, the multiplexing component 845 may be configured as or otherwise support a means for multiplexing the set of multiple sequences to generate the pseudorandom sequence.

In some examples, the control signaling interface 875 may be configured as or otherwise support a means for receiving control signaling indicating a configuration for generating the set of multiple orthogonal or pseudo-orthogonal random sequences, where the set of multiple orthogonal or pseudo-orthogonal random sequences are generated based on the configuration.

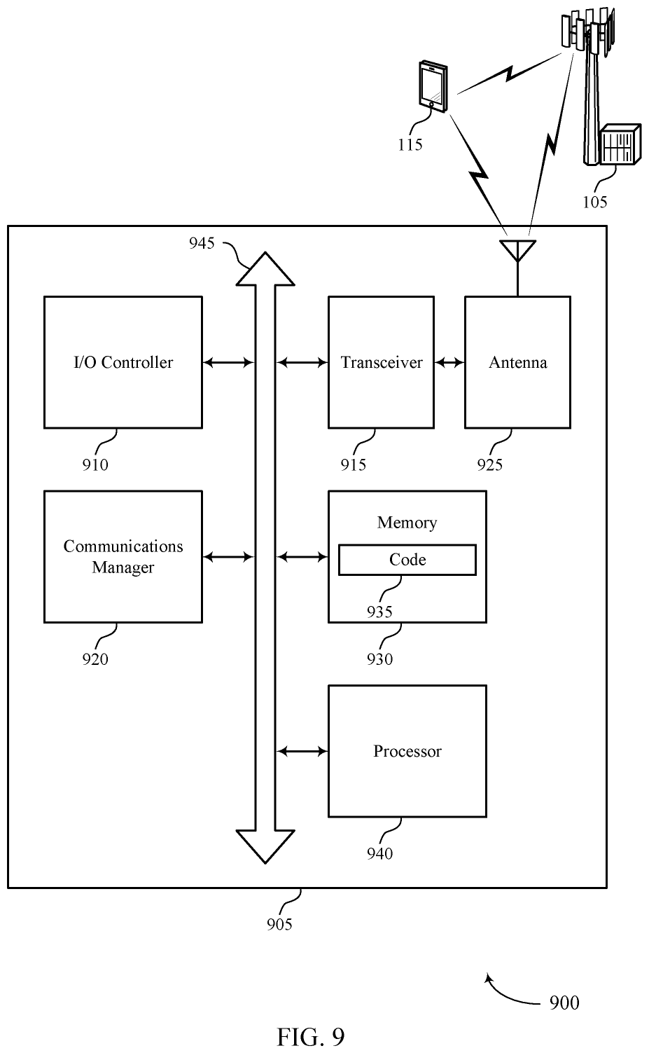

FIG. 9 shows a diagram of a system 900 including a device 905 that supports generation of coded pseudorandom sequences in accordance with one or more aspects of the present disclosure. The device 905 may be an example of or include the components of a device 605, a device 705, or a UE 115 as described herein. The device 905 may communicate (e.g., wirelessly) with one or more network entities 105, one or more UEs 115, or any combination thereof. The device 905 may include components for bi-directional voice and data communications including components for transmitting and receiving communications, such as a communications manager 920, an input/output (I/O) controller 910, a transceiver 915, an antenna 925, a memory 930, code 935, and a processor 940. These components may be in electronic communication or otherwise coupled (e.g., operatively, communicatively, functionally, electronically, electrically) via one or more buses (e.g., a bus 945).

The I/O controller 910 may manage input and output signals for the device 905. The I/O controller 910 may also manage peripherals not integrated into the device 905. In some cases, the I/O controller 910 may represent a physical connection or port to an external peripheral. In some cases, the I/O controller 910 may utilize an operating system such as iOS®, ANDROID®, MS-DOS®, MS-WINDOWS®, OS/2®, UNIX®, LINUX®, or another known operating system. Additionally, or alternatively, the I/O controller 910 may represent or interact with a modem, a keyboard, a mouse, a touchscreen, or a similar device. In some cases, the I/O controller 910 may be implemented as part of a processor, such as the processor 940. In some cases, a user may interact with the device 905 via the I/O controller 910 or via hardware components controlled by the I/O controller 910.

In some cases, the device 905 may include a single antenna 925. However, in some other cases, the device 905 may have more than one antenna 925, which may be capable of concurrently transmitting or receiving multiple wireless transmissions. The transceiver 915 may communicate bi-directionally, via the one or more antennas 925, wired, or wireless links as described herein. For example, the transceiver 915 may represent a wireless transceiver and may communicate bi-directionally with another wireless transceiver. The transceiver 915 may also include a modem to modulate the packets, to provide the modulated packets to one or more antennas 925 for transmission, and to demodulate packets received from the one or more antennas 925. The transceiver 915, or the transceiver 915 and one or more antennas 925, may be an example of a transmitter 615, a transmitter 715, a receiver 610, a receiver 710, or any combination thereof or component thereof, as described herein.

The memory 930 may include random access memory (RAM) and read-only memory (ROM). The memory 930 may store computer-readable, computer-executable code 935 including instructions that, when executed by the processor 940, cause the device 905 to perform various functions described herein. The code 935 may be stored in a non-transitory computer-readable medium such as system memory or another type of memory. In some cases, the code 935 may not be directly executable by the processor 940 but may cause a computer (e.g., when compiled and executed) to perform functions described herein. In some cases, the memory 930 may contain, among other things, a basic I/O system (BIOS) which may control basic hardware or software operation such as the interaction with peripheral components or devices.

The processor 940 may include an intelligent hardware device (e.g., a general-purpose processor, a DSP, a CPU, a GPU, a microcontroller, an ASIC, an FPGA, a programmable logic device, a discrete gate or transistor logic component, a discrete hardware component, or any combination thereof). In some cases, the processor 940 may be configured to operate a memory array using a memory controller. In some other cases, a memory controller may be integrated into the processor 940. The processor 940 may be configured to execute computer-readable instructions stored in a memory (e.g., the memory 930) to cause the device 905 to perform various functions (e.g., functions or tasks supporting generation of coded pseudorandom sequences). For example, the device 905 or a component of the device 905 may include a processor 940 and memory 930 coupled with or to the processor 940, the processor 940 and memory 930 configured to perform various functions described herein.

The communications manager 920 may support wireless communication at a wireless device in accordance with examples as disclosed herein. For example, the communications manager 920 may be configured as or otherwise support a means for segmenting a bit sequence of information bits into a set of multiple bit groups. The communications manager 920 may be configured as or otherwise support a means for mapping each bit group of the set of multiple bit groups to a respective symbol to generating a set of multiple ordered information symbols. The communications manager 920 may be configured as or otherwise support a means for encoding the set of multiple ordered information symbols to generate a set of multiple codewords. The communications manager 920 may be configured as or otherwise support a means for demapping each codeword of the set of multiple codewords to generate a set of multiple sequences. The communications manager 920 may be configured as or otherwise support a means for multiplexing the set of multiple sequences to generate a pseudorandom sequence. The communications manager 920 may be configured as or otherwise support a means for transmitting a signal generated based on the pseudorandom sequence.

Additionally, or alternatively, the communications manager 920 may support wireless communication at a wireless device in accordance with examples as disclosed herein. For example, the communications manager 920 may be configured as or otherwise support a means for generating a set of multiple bit subsets based on a set of multiple ordered information bits. The communications manager 920 may be configured as or otherwise support a means for generating an OCC based on a first subset of the set of multiple bit subsets. The communications manager 920 may be configured as or otherwise support a means for applying the OCC to an input pseudorandom sequence to generate a set of multiple orthogonal or pseudo-orthogonal random sequences. The communications manager 920 may be configured as or otherwise support a means for generating a reference signal based on the set of multiple orthogonal or pseudo-orthogonal random sequences.

By including or configuring the communications manager 920 in accordance with examples as described herein, the device 905 may support techniques for encoded pseudorandom number generation that results in more efficient utilization of communication resources by reducing cross-correlation, thereby improving communication efficiency and reduced inter-cell or intra-cell interference.

In some examples, the communications manager 920 may be configured to perform various operations (e.g., receiving, monitoring, transmitting) using or otherwise in cooperation with the transceiver 915, the one or more antennas 925, or any combination thereof. Although the communications manager 920 is illustrated as a separate component, in some examples, one or more functions described with reference to the communications manager 920 may be supported by or performed by the processor 940, the memory 930, the code 935, or any combination thereof. For example, the code 935 may include instructions for the processor 940 to cause the device 905 to perform various aspects of generation of coded pseudorandom sequences as described herein, or the processor 940 and the memory 930 may be otherwise configured to perform or support such operations.

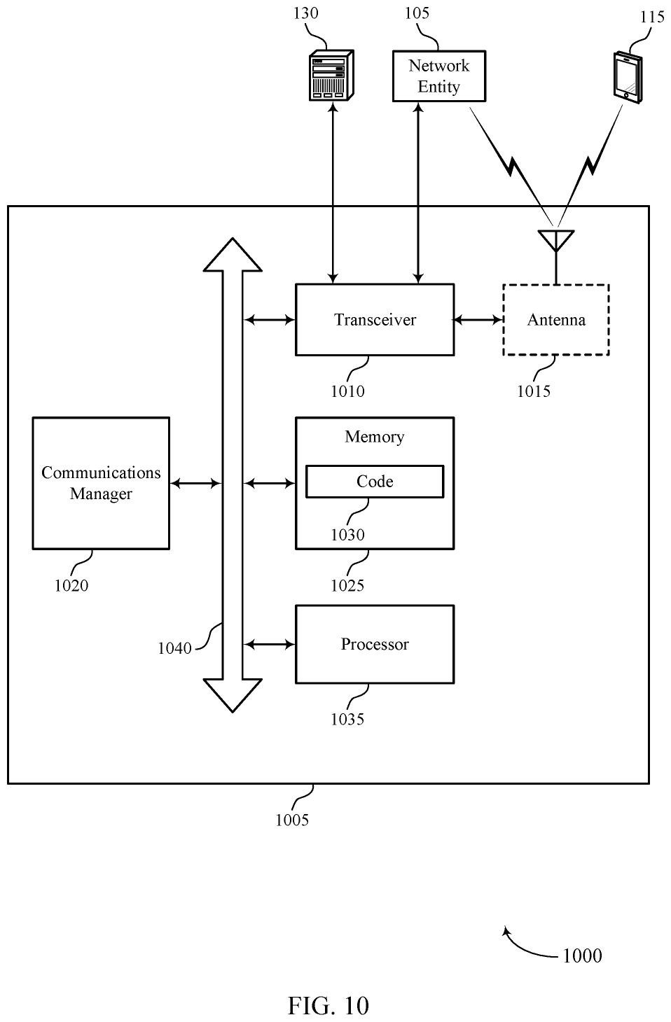

FIG. 10 shows a diagram of a system 1000 including a device 1005 that supports generation of coded pseudorandom sequences in accordance with one or more aspects of the present disclosure. The device 1005 may be an example of or include the components of a device 605, a device 705, or a network entity 105 as described herein. The device 1005 may communicate with one or more network entities 105, one or more UEs 115, or any combination thereof, which may include communications over one or more wired interfaces, over one or more wireless interfaces, or any combination thereof. The device 1005 may include components that support outputting and obtaining communications, such as a communications manager 1020, a transceiver 1010, an antenna 1015, a memory 1025, code 1030, and a processor 1035. These components may be in electronic communication or otherwise coupled (e.g., operatively, communicatively, functionally, electronically, electrically) via one or more buses (e.g., a bus 1040).

The transceiver 1010 may support bi-directional communications via wired links, wireless links, or both as described herein. In some examples, the transceiver 1010 may include a wired transceiver and may communicate bi-directionally with another wired transceiver. Additionally, or alternatively, in some examples, the transceiver 1010 may include a wireless transceiver and may communicate bi-directionally with another wireless transceiver. In some examples, the device 1005 may include one or more antennas 1015, which may be capable of transmitting or receiving wireless transmissions (e.g., concurrently). The transceiver 1010 may also include a modem to modulate signals, to provide the modulated signals for transmission (e.g., by one or more antennas 1015, by a wired transmitter), to receive modulated signals (e.g., from one or more antennas 1015, from a wired receiver), and to demodulate signals. In some implementations, the transceiver 1010 may include one or more interfaces, such as one or more interfaces coupled with the one or more antennas 1015 that are configured to support various receiving or obtaining operations, or one or more interfaces coupled with the one or more antennas 1015 that are configured to support various transmitting or outputting operations, or a combination thereof. In some implementations, the transceiver 1010 may include or be configured for coupling with one or more processors or memory components that are operable to perform or support operations based on received or obtained information or signals, or to generate information or other signals for transmission or other outputting, or any combination thereof. In some implementations, the transceiver 1010, or the transceiver 1010 and the one or more antennas 1015, or the transceiver 1010 and the one or more antennas 1015 and one or more processors or memory components (for example, the processor 1035, or the memory 1025, or both), may be included in a chip or chip assembly that is installed in the device 1005. The transceiver 1010, or the transceiver 1010 and one or more antennas 1015 or wired interfaces, where applicable, may be an example of a transmitter 615, a transmitter 715, a receiver 610, a receiver 710, or any combination thereof or component thereof, as described herein. In some examples, the transceiver may be operable to support communications via one or more communications links (e.g., a communication link 125, a backhaul communication link 120, a midhaul communication link 162, a fronthaul communication link 168).

The memory 1025 may include RAM and ROM. The memory 1025 may store computer-readable, computer-executable code 1030 including instructions that, when executed by the processor 1035, cause the device 1005 to perform various functions described herein. The code 1030 may be stored in a non-transitory computer-readable medium such as system memory or another type of memory. In some cases, the code 1030 may not be directly executable by the processor 1035 but may cause a computer (e.g., when compiled and executed) to perform functions described herein. In some cases, the memory 1025 may contain, among other things, a BIOS which may control basic hardware or software operation such as the interaction with peripheral components or devices.

The processor 1035 may include an intelligent hardware device (e.g., a general-purpose processor, a DSP, an ASIC, a CPU, a GPU, an FPGA, a microcontroller, a programmable logic device, discrete gate or transistor logic, a discrete hardware component, or any combination thereof). In some cases, the processor 1035 may be configured to operate a memory array using a memory controller. In some other cases, a memory controller may be integrated into the processor 1035. The processor 1035 may be configured to execute computer-readable instructions stored in a memory (e.g., the memory 1025) to cause the device 1005 to perform various functions (e.g., functions or tasks supporting generation of coded pseudorandom sequences). For example, the device 1005 or a component of the device 1005 may include a processor 1035 and memory 1025 coupled with the processor 1035, the processor 1035 and memory 1025 configured to perform various functions described herein. The processor 1035 may be an example of a cloud-computing platform (e.g., one or more physical nodes and supporting software such as operating systems, virtual machines, or container instances) that may host the functions (e.g., by executing code 1030) to perform the functions of the device 1005. The processor 1035 may be any one or more suitable processors capable of executing scripts or instructions of one or more software programs stored in the device 1005 (such as within the memory 1025). In some implementations, the processor 1035 may be a component of a processing system. A processing system may generally refer to a system or series of machines or components that receives inputs and processes the inputs to produce a set of outputs (which may be passed to other systems or components of, for example, the device 1005). For example, a processing system of the device 1005 may refer to a system including the various other components or subcomponents of the device 1005, such as the processor 1035, or the transceiver 1010, or the communications manager 1020, or other components or combinations of components of the device 1005. The processing system of the device 1005 may interface with other components of the device 1005, and may process information received from other components (such as inputs or signals) or output information to other components. For example, a chip or modem of the device 1005 may include a processing system and an interface to output information, or to obtain information, or both. The interface may be implemented as or otherwise include a first interface configured to output information and a second interface configured to obtain information. In some implementations, the first interface may refer to an interface between the processing system of the chip or modem and a transmitter, such that the device 1005 may transmit information output from the chip or modem. In some implementations, the second interface may refer to an interface between the processing system of the chip or modem and a receiver, such that the device 1005 may obtain information or signal inputs, and the information may be passed to the processing system. A person having ordinary skill in the art will readily recognize that the first interface also may obtain information or signal inputs, and the second interface also may output information or signal outputs.

In some examples, a bus 1040 may support communications of (e.g., within) a protocol layer of a protocol stack. In some examples, a bus 1040 may support communications associated with a logical channel of a protocol stack (e.g., between protocol layers of a protocol stack), which may include communications performed within a component of the device 1005, or between different components of the device 1005 that may be co-located or located in different locations (e.g., where the device 1005 may refer to a system in which one or more of the communications manager 1020, the transceiver 1010, the memory 1025, the code 1030, and the processor 1035 may be located in one of the different components or divided between different components).

In some examples, the communications manager 1020 may manage aspects of communications with a core network 130 (e.g., via one or more wired or wireless backhaul links). For example, the communications manager 1020 may manage the transfer of data communications for client devices, such as one or more UEs 115. In some examples, the communications manager 1020 may manage communications with other network entities 105, and may include a controller or scheduler for controlling communications with UEs 115 in cooperation with other network entities 105. In some examples, the communications manager 1020 may support an X2 interface within an LTE/LTE-A wireless communications network technology to provide communication between network entities 105.

The communications manager 1020 may support wireless communication at a wireless device in accordance with examples as disclosed herein. For example, the communications manager 1020 may be configured as or otherwise support a means for segmenting a bit sequence of information bits into a set of multiple bit groups. The communications manager 1020 may be configured as or otherwise support a means for mapping each bit group of the set of multiple bit groups to a respective symbol to generating a set of multiple ordered information symbols. The communications manager 1020 may be configured as or otherwise support a means for encoding the set of multiple ordered information symbols to generate a set of multiple codewords. The communications manager 1020 may be configured as or otherwise support a means for demapping each codeword of the set of multiple codewords to generate a set of multiple sequences. The communications manager 1020 may be configured as or otherwise support a means for multiplexing the set of multiple sequences to generate a pseudorandom sequence. The communications manager 1020 may be configured as or otherwise support a means for transmitting a signal generated based on the pseudorandom sequence.

Additionally, or alternatively, the communications manager 1020 may support wireless communication at a wireless device in accordance with examples as disclosed herein. For example, the communications manager 1020 may be configured as or otherwise support a means for generating a set of multiple bit subsets based on a set of multiple ordered information bits. The communications manager 1020 may be configured as or otherwise support a means for generating an OCC based on a first subset of the set of multiple bit subsets. The communications manager 1020 may be configured as or otherwise support a means for applying the OCC to an input pseudorandom sequence to generate a set of multiple orthogonal or pseudo-orthogonal random sequences. The communications manager 1020 may be configured as or otherwise support a means for generating a reference signal based on the set of multiple orthogonal or pseudo-orthogonal random sequences.

By including or configuring the communications manager 1020 in accordance with examples as described herein, the device 1005 may support techniques for encoded pseudorandom number generation that results in more efficient utilization of communication resources by reducing cross-correlation, thereby improving communication efficiency.

In some examples, the communications manager 1020 may be configured to perform various operations (e.g., receiving, obtaining, monitoring, outputting, transmitting) using or otherwise in cooperation with the transceiver 1010, the one or more antennas 1015 (e.g., where applicable), or any combination thereof. Although the communications manager 1020 is illustrated as a separate component, in some examples, one or more functions described with reference to the communications manager 1020 may be supported by or performed by the processor 1035, the memory 1025, the code 1030, the transceiver 1010, or any combination thereof. For example, the code 1030 may include instructions for the processor 1035 to cause the device 1005 to perform various aspects of generation of coded pseudorandom sequences as described herein, or the processor 1035 and the memory 1025 may be otherwise configured to perform or support such operations.

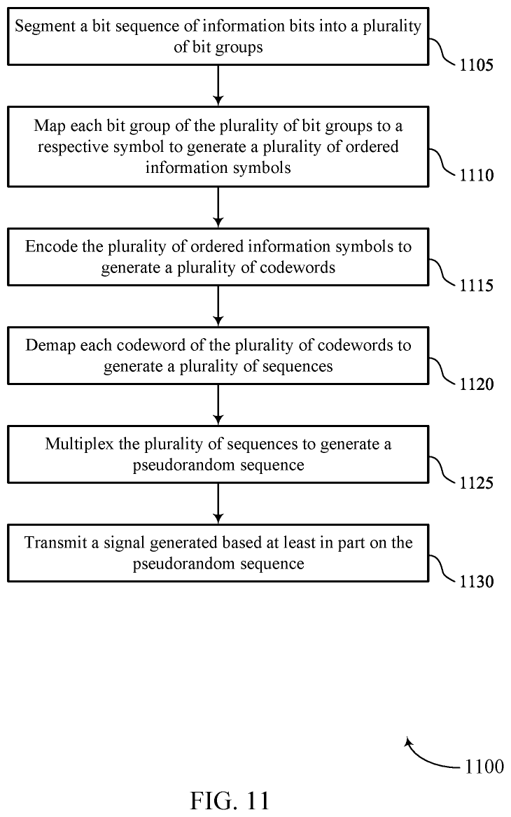

FIG. 11 shows a flowchart illustrating a method 1100 that supports generation of coded pseudorandom sequences in accordance with one or more aspects of the present disclosure. The operations of the method 1100 may be implemented by a UE or a network entity or its components as described herein. For example, the operations of the method 1100 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1105, the method may include segmenting a bit sequence of information bits into a plurality of bit groups. The operations of 1105 may be performed in accordance with examples as disclosed herein. In some examples, aspects of the operations of 1105 may be performed by a bit sequence segmentation component 825 as described with reference to FIG. 8.

At 1110, the method may include mapping each bit group of the plurality of bit groups to a respective symbol to generate a plurality of ordered information symbols. The operations of 1110 may be performed in accordance with examples as disclosed herein. In some examples, aspects of the operations of 1110 may be performed by a bit group mapping component 830 as described with reference to FIG. 8.

At 1115, the method may include encoding the plurality of ordered information symbols to generate a plurality of codewords. The operations of 1115 may be performed in accordance with examples as disclosed herein. In some examples, aspects of the operations of 1115 may be performed by an encoder 835 as described with reference to FIG. 8.

At 1120, the method may include demapping each codeword of the plurality of codewords to generate a plurality of sequences. The operations of 1120 may be performed in accordance with examples as disclosed herein. In some examples, aspects of the operations of 1120 may be performed by a demapping component 840 as described with reference to FIG. 8.

At 1125, the method may include multiplexing the plurality of sequences to generate a pseudorandom sequence. The operations of 1125 may be performed in accordance with examples as disclosed herein. In some examples, aspects of the operations of 1125 may be performed by a multiplexing component 845 as described with reference to FIG. 8.

At 1130, the method may include transmitting a signal generated based at least in part on the pseudorandom sequence. The operations of 1130 may be performed in accordance with examples as disclosed herein. In some examples, aspects of the operations of 1130 may be performed by a signal interface 850 as described with reference to FIG. 8.

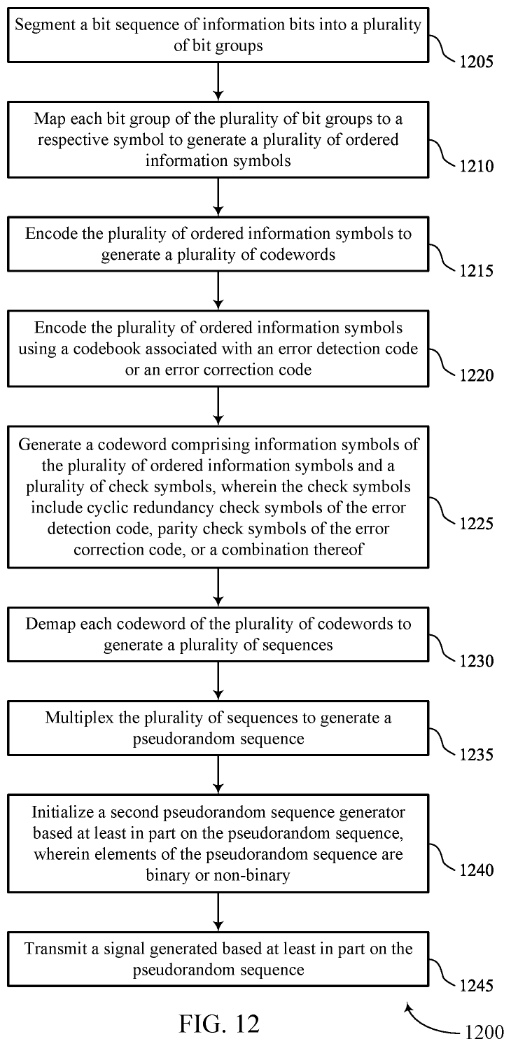

FIG. 12 shows a flowchart illustrating a method 1200 that supports generation of coded pseudorandom sequences in accordance with one or more aspects of the present disclosure. The operations of the method 1200 may be implemented by a UE or a network entity or its components as described herein. For example, the operations of the method 1200 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1205, the method may include segmenting a bit sequence of information bits into a plurality of bit groups. The operations of 1205 may be performed in accordance with examples as disclosed herein. In some examples, aspects of the operations of 1205 may be performed by a bit sequence segmentation component 825 as described with reference to FIG. 8.

At 1210, the method may include mapping each bit group of the plurality of bit groups to a respective symbol to generate a plurality of ordered information symbols. The operations of 1210 may be performed in accordance with examples as disclosed herein. In some examples, aspects of the operations of 1210 may be performed by a bit group mapping component 830 as described with reference to FIG. 8.

At 1215, the method may include encoding the plurality of ordered information symbols to generate a plurality of codewords. The operations of 1215 may be performed in accordance with examples as disclosed herein. In some examples, aspects of the operations of 1215 may be performed by an encoder 835 as described with reference to FIG. 8.

At 1220, the method may include encoding the plurality of ordered information symbols using a codebook associated with an error detection code or an error correction code. The operations of 1220 may be performed in accordance with examples as disclosed herein. In some examples, aspects of the operations of 1220 may be performed by an encoder 835 as described with reference to FIG. 8.

At 1225, the method may include generating a codeword comprising information symbols of the plurality of ordered information symbols and a plurality of check symbols, wherein the check symbols include cyclic redundancy check symbols of the error detection code, parity check symbols of the error correction code, or a combination thereof. The operations of 1225 may be performed in accordance with examples as disclosed herein. In some examples, aspects of the operations of 1225 may be performed by an encoder 835 as described with reference to FIG. 8.

At 1230, the method may include demapping each codeword of the plurality of codewords to generate a plurality of sequences. The operations of 1230 may be performed in accordance with examples as disclosed herein. In some examples, aspects of the operations of 1230 may be performed by a demapping component 840 as described with reference to FIG. 8.

At 1235, the method may include multiplexing the plurality of sequences to generate a pseudorandom sequence. The operations of 1235 may be performed in accordance with examples as disclosed herein. In some examples, aspects of the operations of 1235 may be performed by a multiplexing component 845 as described with reference to FIG. 8.

At 1240, the method may include initializing a second pseudorandom sequence generator based at least in part on the pseudorandom sequence, wherein elements of the pseudorandom sequence are binary or non-binary. The operations of 1240 may be performed in accordance with examples as disclosed herein. In some examples, aspects of the operations of 1240 may be performed by a second pseudorandom sequence component 890 as described with reference to FIG. 8.

At 1245, the method may include transmitting a signal generated based at least in part on the pseudorandom sequence. The operations of 1245 may be performed in accordance with examples as disclosed herein. In some examples, aspects of the operations of 1245 may be performed by a signal interface 850 as described with reference to FIG. 8.

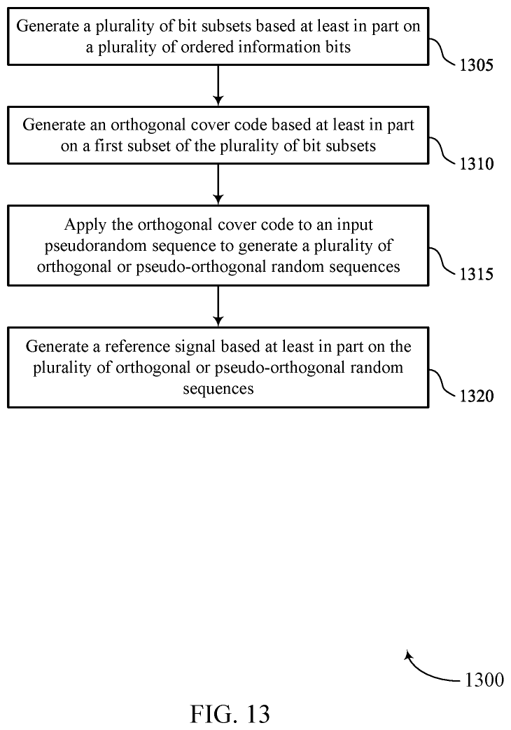

FIG. 13 shows a flowchart illustrating a method 1300 that supports generation of coded pseudorandom sequences in accordance with one or more aspects of the present disclosure. The operations of the method 1300 may be implemented by a UE or a network entity or its components as described herein. For example, the operations of the method 1300 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1305, the method may include generating a plurality of bit subsets based at least in part on a plurality of ordered information bits. The operations of 1305 may be performed in accordance with examples as disclosed herein. In some examples, aspects of the operations of 1305 may be performed by a bit subset component 855 as described with reference to FIG. 8.

At 1310, the method may include generating an orthogonal cover code based at least in part on a first subset of the plurality of bit subsets. The operations of 1310 may be performed in accordance with examples as disclosed herein. In some examples, aspects of the operations of 1310 may be performed by a OCC generation component 860 as described with reference to FIG. 8.

At 1315, the method may include applying the orthogonal cover code to an input pseudorandom sequence to generate a plurality of orthogonal or pseudo-orthogonal random sequences. The operations of 1315 may be performed in accordance with examples as disclosed herein. In some examples, aspects of the operations of 1315 may be performed by a OCC application component 865 as described with reference to FIG. 8.

At 1320, the method may include generating a reference signal based at least in part on the plurality of orthogonal or pseudo-orthogonal random sequences. The operations of 1320 may be performed in accordance with examples as disclosed herein. In some examples, aspects of the operations of 1320 may be performed by a reference signal component 870 as described with reference to FIG. 8.

The following provides an overview of aspects of the present disclosure:
Aspect 1: A method for wireless communication at a wireless device, comprising: segmenting a bit sequence of information bits into a plurality of bit groups; mapping each bit group of the plurality of bit groups to a respective symbol to generate a plurality of ordered information symbols; encoding the plurality of ordered information symbols to generate a plurality of codewords; demapping each codeword of the plurality of codewords to generate a plurality of sequences; multiplexing the plurality of sequences to generate a pseudorandom sequence; and transmitting a signal generated based at least in part on the pseudorandom sequence.

Aspect 2: The method of aspect 1, further comprising: receiving control signaling that indicates that the wireless device is to use single-stage randomization or multi-stage randomization, wherein the pseudorandom sequence is generated based at least in part on multi-stage randomization.

Aspect 3: The method of any of aspects 1 through 2, further comprising: receiving control signaling that indicates that the wireless device is to use an orthogonal cover code to generate a plurality of orthogonal sequences based at least in part on the pseudorandom sequence, wherein the signal is generated based at least in part on the orthogonal cover code.

Aspect 4: The method of any of aspects 1 through 3, further comprising: receiving control signaling that indicates a configuration for generating the pseudorandom sequence, wherein pseudorandom sequence is generated based at least in part on the configuration.

Aspect 5: The method of any of aspects 1 through 4, wherein encoding the plurality of ordered information symbols comprises: encoding the plurality of ordered information symbols using a codebook associated with an error detection code or an error correction code; and generating a codeword comprising information symbols of the plurality of ordered information symbols and a plurality of check symbols, wherein the check symbols include cyclic redundancy check symbols of the error detection code, parity check symbols of the error correction code, or a combination thereof.

Aspect 6: The method of aspect 5, wherein codewords in the codebook have a defined separation distance for a given code rate or a given codebook size.

Aspect 7: The method of any of aspects 5 through 6, wherein the codeword is generated using an error detection coding algorithm that is a Reed-Solomon code or a Bose-Chaudhuri-Hocquenghem code.

Aspect 8: The method of any of aspects 1 through 7, further comprising: zero-padding each subset of information bits of a plurality of subsets of information bits, each subset of information bits corresponding to an information symbol defined on a finite field, wherein the zero-padding results in the bit sequence of information bits.

Aspect 9: The method of any of aspects 1 through 8, further comprising: processing a plurality of subsets of information bits, each subset of information bits corresponding to an information symbol, the processing including multiplexing, interleaving, or both the plurality of subsets of information bits resulting in the plurality of ordered information symbols.

Aspect 10: The method of any of aspects 1 through 9, further comprising: initializing a second pseudorandom sequence generator based at least in part on the pseudorandom sequence, wherein elements of the pseudorandom sequence are binary or non-binary.

Aspect 11: The method of aspect 10, wherein the second pseudorandom sequence generator comprises one or more linear-feedback shift registers; and operation of the one or more linear-feedback shift registers is defined on a binary finite field or a non-binary finite field.

Aspect 12: The method of aspect 10, wherein initializing the second pseudorandom sequence generator comprises: using the pseudorandom sequence that is coded and comprises a plurality of information symbols and check symbols as input into the initialized second pseudorandom sequence generator.

Aspect 13: The method of any of aspects 1 through 12, further comprising: generating a plurality of bit subsets based at least in part on a plurality of ordered information bits; generating an orthogonal cover code based at least in part on a first subset of the plurality of bit subsets; applying the orthogonal cover code to the pseudorandom sequence to generate a plurality of orthogonal or pseudo-orthogonal random sequences; and generating a reference signal based at least in part on the plurality of orthogonal or pseudo-orthogonal random sequences.

Aspect 14: The method of aspect 13, further comprising: multiplexing the plurality of orthogonal or pseudo-orthogonal random sequences to generate a multiplexed signal, wherein the reference signal is generated based at least in part on the multiplexed plurality of orthogonal or pseudo-orthogonal random sequences.

Aspect 15: The method of any of aspects 13 through 14, wherein generating the orthogonal cover code comprises: generating the orthogonal cover code using a closed-form formula comprising a Walsh-Hadamard code, a constant amplitude zero autocorrelation waveform sequence, a chirp sequence, or any combination thereof.

Aspect 16: The method of any of aspects 13 through 15, wherein applying the orthogonal cover code comprises: multiplying each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is segmented to generate the plurality of pseudorandom symbol subsets.

Aspect 17: The method of any of aspects 13 through 15, wherein applying the orthogonal cover code comprises: multiplying each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is repeated to generate the plurality of pseudorandom symbol subsets.

Aspect 18: The method of any of aspects 13 through 15, wherein applying the orthogonal cover code comprises: multiplying each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is concatenated with one or more second pseudorandom sequences to generate the plurality of pseudorandom symbol sub sets.

Aspect 19: A method for wireless communication at a wireless device, comprising: generating a plurality of bit subsets based at least in part on a plurality of ordered information bits; generating an orthogonal cover code based at least in part on a first subset of the plurality of bit subsets; applying the orthogonal cover code to an input pseudorandom sequence to generate a plurality of orthogonal or pseudo-orthogonal random sequences; and generating a reference signal based at least in part on the plurality of orthogonal or pseudo-orthogonal random sequences.

Aspect 20: The method of aspect 19, further comprising: multiplexing the plurality of orthogonal or pseudo-orthogonal random sequences to generate a multiplexed signal, wherein the reference signal is generated based at least in part on the multiplexed plurality of orthogonal or pseudo-orthogonal random sequences.

Aspect 21: The method of any of aspects 19 through 20, wherein generating the orthogonal cover code comprises: generating the orthogonal cover code using a closed-form formula that is a Walsh-Hadamard code, or a constant amplitude zero autocorrelation waveform sequence, or a chirp sequence, or any combination thereof.

Aspect 22: The method of any of aspects 19 through 21, wherein applying the orthogonal cover code comprises: multiplying each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is segmented to generate the plurality of pseudorandom symbol subsets.

Aspect 23: The method of any of aspects 19 through 21, wherein applying the orthogonal cover code comprises: multiplying each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is repeated to generate the plurality of pseudorandom symbol subsets.

Aspect 24: The method of any of aspects 19 through 21, wherein applying the orthogonal cover code comprises: multiplying each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is concatenated with one or more second pseudorandom sequences to generate the plurality of pseudorandom symbol sub sets.

Aspect 25: The method of any of aspects 19 through 24, further comprising: segmenting a bit sequence of information bits into a plurality of bit groups; mapping each bit group of the plurality of bit groups to a respective symbol to generate a plurality of ordered information symbols; encoding the plurality of ordered information symbols to generate a plurality of codewords; demapping each codeword of the plurality of codewords to generate a plurality of sequences; and multiplexing the plurality of sequences to generate a pseudorandom sequence that includes the plurality of ordered information symbols.

Aspect 26: The method of any of aspects 19 through 25, further comprising: receiving control signaling indicating a configuration for generating the plurality of orthogonal or pseudo-orthogonal random sequences, wherein the plurality of orthogonal or pseudo-orthogonal random sequences are generated based at least in part on the configuration.

Aspect 27: An apparatus for wireless communication at a wireless device, comprising a processor; and memory coupled with the processor, the memory storing instructions for the processor to cause the wireless device to perform a method of any of aspects 1 through 18.

Aspect 28: An apparatus for wireless communication at a wireless device, comprising at least one means for performing a method of any of aspects 1 through 18.

Aspect 29: A non-transitory computer-readable medium storing code for wireless communication at a wireless device, the code comprising instructions for a processor to perform a method of any of aspects 1 through 18.

Aspect 30: An apparatus for wireless communication at a wireless device, comprising a processor; and memory coupled with the processor, the memory storing instructions for the processor to cause the wireless device to perform a method of any of aspects 19 through 26.

Aspect 31: An apparatus for wireless communication at a wireless device, comprising at least one means for performing a method of any of aspects 19 through 26.

Aspect 32: A non-transitory computer-readable medium storing code for wireless communication at a wireless device, the code comprising instructions for a processor to perform a method of any of aspects 19 through 26.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a GPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented using hardware, software executed by a processor, or any combination thereof. Software shall be construed broadly to mean instructions, instruction sets, code, code segments, program code, programs, subprograms, software modules, applications, software applications, software packages, routines, subroutines, objects, executables, threads of execution, procedures, or functions, whether referred to as software, firmware, middleware, microcode, hardware description language, or otherwise. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, phase change memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, including in the claims, “or” as used in a list of items (e.g., including a list of items prefaced by a phrase such as “at least one of” or “one or more of”) indicates an inclusive list such that, for example, a list of at least one of A, B, or C means, e.g., A or B or C or AB or AC or BC or ABC (e.g., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.” As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

The term “determine” or “determining” or “identify” or “identifying” encompasses a variety of actions and, therefore, “determining” or “identifying” can include calculating, computing, processing, deriving, investigating, looking up (such as via looking up in a table, a database or another data structure), ascertaining and the like. Also, “determining” or “identifying” can include receiving (such as receiving information or signaling, e.g., receiving information or signaling for determining, receiving information or signaling for identifying), accessing (such as accessing data in a memory, or accessing information) and the like. Also, “determining” or “identifying” can include resolving, obtaining, selecting, choosing, establishing and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus for wireless communication at a wireless device, comprising:
a processor; and
memory coupled with the processor, the memory storing instructions for the processor to cause the wireless device to:
segment a bit sequence of information bits into a plurality of bit groups;
map each bit group of the plurality of bit groups to a respective symbol to generate a plurality of ordered information symbols;
encode the plurality of ordered information symbols to generate a plurality of codewords;
demap each codeword of the plurality of codewords to generate a plurality of sequences;
multiplex the plurality of sequences to generate a pseudorandom sequence; and
transmit a signal generated based at least in part on the pseudorandom sequence.

2. The apparatus of claim 1, wherein the instructions are further for the processor to cause the wireless device to:
receive control signaling that indicates that the wireless device is to use single-stage randomization or multi-stage randomization, wherein the pseudorandom sequence is generated based at least in part on multi-stage randomization.

3. The apparatus of claim 1, wherein the instructions are further for the processor to cause the wireless device to:
receive control signaling that indicates that the wireless device is to use an orthogonal cover code to generate a plurality of orthogonal sequences based at least in part on the pseudorandom sequence, wherein the signal is generated based at least in part on the orthogonal cover code.

4. The apparatus of claim 1, wherein the instructions are further for the processor to cause the wireless device to:
receive control signaling that indicates a configuration for generating the pseudorandom sequence, wherein pseudorandom sequence is generated based at least in part on the configuration.

5. The apparatus of claim 1, wherein the instructions to encode the plurality of ordered information symbols are for the processor to cause the wireless device to:
encode the plurality of ordered information symbols using a codebook associated with an error detection code or an error correction code; and
generate a codeword comprising information symbols of the plurality of ordered information symbols and a plurality of check symbols, wherein the check symbols include cyclic redundancy check symbols of the error detection code, parity check symbols of the error correction code, or a combination thereof.

6. The apparatus of claim 5, wherein codewords in the codebook have a defined separation distance for a given code rate or a given codebook size.

7. The apparatus of claim 5, wherein the codeword is generated using an error detection coding algorithm that is a Reed-Solomon code or a Bose-Chaudhuri-Hocquenghem code.

8. The apparatus of claim 1, wherein the instructions are further for the processor to cause the wireless device to:
zero-pad each subset of information bits of a plurality of subsets of information bits, each subset of information bits correspond to an information symbol defined on a finite field, wherein the zero-padding results in the bit sequence of information bits.

9. The apparatus of claim 1, wherein the instructions are further for the processor to cause the wireless device to:
process a plurality of subsets of information bits, each subset of information bits corresponding to an information symbol, the processing including multiplexing, interleaving, or both the plurality of subsets of information bits resulting in the plurality of ordered information symbols.

10. The apparatus of claim 1, wherein the instructions are further for the processor to cause the wireless device to:
initialize a second pseudorandom sequence generator based at least in part on the pseudorandom sequence, wherein elements of the pseudorandom sequence are binary or non-binary.

11. The apparatus of claim 10, wherein:
the second pseudorandom sequence generator comprises one or more linear-feedback shift registers; and
operation of the one or more linear-feedback shift registers is defined on a binary finite field or a non-binary finite field.

12. The apparatus of claim 10, wherein the instructions to initialize the second pseudorandom sequence generator are for the processor to cause the wireless device to:
use the pseudorandom sequence that is coded and comprises a plurality of information symbols and check symbols as input into the initialized second pseudorandom sequence generator.

13. The apparatus of claim 1, wherein the instructions are further for the processor to cause the wireless device to:
generate a plurality of bit subsets based at least in part on a plurality of ordered information bits;
generate an orthogonal cover code based at least in part on a first subset of the plurality of bit subsets;
apply the orthogonal cover code to the pseudorandom sequence to generate a plurality of orthogonal or pseudo-orthogonal random sequences; and
generate a reference signal based at least in part on the plurality of orthogonal or pseudo-orthogonal random sequences.

14. The apparatus of claim 13, wherein the instructions are further for the processor to cause the wireless device to:
multiplex the plurality of orthogonal or pseudo-orthogonal random sequences to generate a multiplexed signal, wherein the reference signal is generated based at least in part on the multiplexed plurality of orthogonal or pseudo-orthogonal random sequences.

15. The apparatus of claim 13, wherein the instructions to generate the orthogonal cover code are for the processor to cause the wireless device to:
generate the orthogonal cover code using a closed-form formula comprising a Walsh-Hadamard code, a constant amplitude zero autocorrelation waveform sequence, a chirp sequence, or any combination thereof.

16. The apparatus of claim 13, wherein the instructions to apply the orthogonal cover code are for the processor to cause the wireless device to:
multiply each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is segmented to generate the plurality of pseudorandom symbol subsets.

17. The apparatus of claim 13, wherein the instructions to apply the orthogonal cover code are for the processor to cause the wireless device to:
multiply each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is repeated to generate the plurality of pseudorandom symbol subsets.

18. The apparatus of claim 13, wherein the instructions to apply the orthogonal cover code are for the processor to cause the wireless device to:
multiply each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is concatenated with one or more second pseudorandom sequences to generate the plurality of pseudorandom symbol subsets.

19. An apparatus for wireless communication at a wireless device, comprising:
a processor; and
memory coupled with the processor, the memory storing instructions for the processor to cause the wireless device to:
generate a plurality of bit subsets based at least in part on a plurality of ordered information bits;
generate an orthogonal cover code based at least in part on a first subset of the plurality of bit subsets;
apply the orthogonal cover code to an input pseudorandom sequence to generate a plurality of orthogonal or pseudo-orthogonal random sequences; and
generate a reference signal based at least in part on the plurality of orthogonal or pseudo-orthogonal random sequences.

20. The apparatus of claim 19, wherein the instructions are further for the processor to cause the wireless device to:
multiplex the plurality of orthogonal or pseudo-orthogonal random sequences to generate a multiplexed signal, wherein the reference signal is generated based at least in part on the multiplexed plurality of orthogonal or pseudo-orthogonal random sequences.

21. The apparatus of claim 19, wherein the instructions to generate the orthogonal cover code are for the processor to cause the wireless device to:
generate the orthogonal cover code using a closed-form formula that is a Walsh-Hadamard code, or a constant amplitude zero autocorrelation waveform sequence, or a chirp sequence, or any combination thereof.

22. The apparatus of claim 19, wherein the instructions to apply the orthogonal cover code are for the processor to cause the wireless device to:
multiply each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is segmented to generate the plurality of pseudorandom symbol subsets.

23. The apparatus of claim 19, wherein the instructions to apply the orthogonal cover code are for the processor to cause the wireless device to:
multiply each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is repeated to generate the plurality of pseudorandom symbol subsets.

24. The apparatus of claim 19, wherein the instructions to apply the orthogonal cover code are for the processor to cause the wireless device to:
multiply each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is concatenated with one or more second pseudorandom sequences to generate the plurality of pseudorandom symbol subsets.

25. The apparatus of claim 19, wherein the instructions are further for the processor to cause the wireless device to:
segment a bit sequence of information bits into a plurality of bit groups;
map each bit group of the plurality of bit groups to a respective symbol to generate a plurality of ordered information symbols;
encode the plurality of ordered information symbols to generate a plurality of codewords;
demap each codeword of the plurality of codewords to generate a plurality of sequences; and
multiplex the plurality of sequences to generate a pseudorandom sequence that includes the plurality of ordered information symbols.

26. The apparatus of claim 19, wherein the instructions are further for the processor to cause the wireless device to:
receive control signaling indicating a configuration for generating the plurality of orthogonal or pseudo-orthogonal random sequences, wherein the plurality of orthogonal or pseudo-orthogonal random sequences are generated based at least in part on the configuration.

27. A method for wireless communication at a wireless device, comprising:
segmenting a bit sequence of information bits into a plurality of bit groups;
mapping each bit group of the plurality of bit groups to a respective symbol to generate a plurality of ordered information symbols;
encoding the plurality of ordered information symbols to generate a plurality of codewords;
demapping each codeword of the plurality of codewords to generate a plurality of sequences;
multiplexing the plurality of sequences to generate a pseudorandom sequence; and
transmitting a signal generated based at least in part on the pseudorandom sequence.

28. The method of claim 27, further comprising:
receiving control signaling that indicates that the wireless device is to use single-stage randomization or multi-stage randomization, wherein the pseudorandom sequence is generated based at least in part on multi-stage randomization.

29. The method of claim 27, further comprising:
receiving control signaling that indicates that the wireless device is to use an orthogonal cover code to generate a plurality of orthogonal sequences based at least in part on the pseudorandom sequence, wherein the signal is generated based at least in part on the orthogonal cover code.

30. The method of claim 27, further comprising:
receiving control signaling that indicates a configuration for generating the pseudorandom sequence, wherein pseudorandom sequence is generated based at least in part on the configuration.

31. The method of claim 27, wherein encoding the plurality of ordered information symbols comprises:
encoding the plurality of ordered information symbols using a codebook associated with an error detection code or an error correction code; and
generating a codeword comprising information symbols of the plurality of ordered information symbols and a plurality of check symbols, wherein the check symbols include cyclic redundancy check symbols of the error detection code, parity check symbols of the error correction code, or a combination thereof.

32. The method of claim 31, wherein codewords in the codebook have a defined separation distance for a given code rate or a given codebook size.

33. The method of claim 31, wherein the codeword is generated using an error detection coding algorithm that is a Reed-Solomon code or a Bose-Chaudhuri-Hocquenghem code.

34. The method of claim 27, further comprising:
zero-padding each subset of information bits of a plurality of subsets of information bits, each subset of information bits corresponding to an information symbol defined on a finite field, wherein the zero-padding results in the bit sequence of information bits.

35. The method of claim 27, further comprising:
processing a plurality of subsets of information bits, each subset of information bits corresponding to an information symbol, the processing including multiplexing, interleaving, or both the plurality of subsets of information bits resulting in the plurality of ordered information symbols.

36. The method of claim 27, further comprising:
initializing a second pseudorandom sequence generator based at least in part on the pseudorandom sequence, wherein elements of the pseudorandom sequence are binary or non-binary.

37. The method of claim 36, wherein:
the second pseudorandom sequence generator comprises one or more linear-feedback shift registers; and
operation of the one or more linear-feedback shift registers is defined on a binary finite field or a non-binary finite field.

38. The method of claim 36, wherein initializing the second pseudorandom sequence generator comprises:
using the pseudorandom sequence that is coded and comprises a plurality of information symbols and check symbols as input into the initialized second pseudorandom sequence generator.

39. The method of claim 27, further comprising:
generating a plurality of bit subsets based at least in part on a plurality of ordered information bits;
generating an orthogonal cover code based at least in part on a first subset of the plurality of bit subsets;
applying the orthogonal cover code to the pseudorandom sequence to generate a plurality of orthogonal or pseudo-orthogonal random sequences; and
generating a reference signal based at least in part on the plurality of orthogonal or pseudo-orthogonal random sequences.

40. The method of claim 39, further comprising:
multiplexing the plurality of orthogonal or pseudo-orthogonal random sequences to generate a multiplexed signal, wherein the reference signal is generated based at least in part on the multiplexed plurality of orthogonal or pseudo-orthogonal random sequences.

41. The method of claim 39, wherein generating the orthogonal cover code comprises:
generating the orthogonal cover code using a closed-form formula comprising a Walsh-Hadamard code, a constant amplitude zero autocorrelation waveform sequence, a chirp sequence, or any combination thereof.

42. The method of claim 39, wherein applying the orthogonal cover code comprises:
multiplying each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is segmented to generate the plurality of pseudorandom symbol subsets.

43. The method of claim 39, wherein applying the orthogonal cover code comprises:
multiplying each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is repeated to generate the plurality of pseudorandom symbol subsets.

44. The method of claim 39, wherein applying the orthogonal cover code comprises:
multiplying each pseudorandom symbol subset of a plurality of pseudorandom symbol subsets by a respective symbol of the orthogonal cover code to generate the plurality of orthogonal or pseudo-orthogonal random sequences, wherein the pseudorandom sequence is concatenated with one or more second pseudorandom sequences to generate the plurality of pseudorandom symbol subsets.

45. A method for wireless communication at a wireless device, comprising:
generating a plurality of bit subsets based at least in part on a plurality of ordered information bits;
generating an orthogonal cover code based at least in part on a first subset of the plurality of bit subsets;
applying the orthogonal cover code to an input pseudorandom sequence to generate a plurality of orthogonal or pseudo-orthogonal random sequences; and
generating a reference signal based at least in part on the plurality of orthogonal or pseudo-orthogonal random sequences.

46. The method of claim 45, further comprising:
multiplexing the plurality of orthogonal or pseudo-orthogonal random sequences to generate a multiplexed signal, wherein the reference signal is generated based at least in part on the multiplexed plurality of orthogonal or pseudo-orthogonal random sequences.

47. The method of claim 45, wherein generating the orthogonal cover code comprises:
generating the orthogonal cover code using a closed-form formula that is a Walsh-Hadamard code, or a constant amplitude zero autocorrelation waveform sequence, or a chirp sequence, or any combination thereof.

48. The method of claim 45, wherein applying the orthogonal cover code comprises:
multiplying each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is segmented to generate the plurality of pseudorandom symbol subsets.

49. The method of claim 45, wherein applying the orthogonal cover code comprises:
multiplying each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is repeated to generate the plurality of pseudorandom symbol subsets.

50. The method of claim 45, wherein applying the orthogonal cover code comprises:
multiplying each pseudorandom symbol subset of a plurality of pseudorandom symbol subsets by a respective symbol of the orthogonal cover code to generate the plurality of orthogonal or pseudo-orthogonal random sequences, wherein the input pseudorandom sequence is concatenated with one or more second pseudorandom sequences to generate the plurality of pseudorandom symbol subsets.

51. The method of claim 45, further comprising:
segmenting a bit sequence of information bits into a plurality of bit groups;
mapping each bit group of the plurality of bit groups to a respective symbol to generate a plurality of ordered information symbols;
encoding the plurality of ordered information symbols to generate a plurality of codewords;
demapping each codeword of the plurality of codewords to generate a plurality of sequences; and
multiplexing the plurality of sequences to generate a pseudorandom sequence that includes the plurality of ordered information symbols.

52. The method of claim 45, further comprising:
receiving control signaling indicating a configuration for generating the plurality of orthogonal or pseudo-orthogonal random sequences, wherein the plurality of orthogonal or pseudo-orthogonal random sequences are generated based at least in part on the configuration.

53. An apparatus for wireless communication at a wireless device, comprising:
means for segmenting a bit sequence of information bits into a plurality of bit groups;
means for mapping each bit group of the plurality of bit groups to a respective symbol to generate a plurality of ordered information symbols;
means for encoding the plurality of ordered information symbols to generate a plurality of codewords;
means for demapping each codeword of the plurality of codewords to generate a plurality of sequences;
means for multiplexing the plurality of sequences to generate a pseudorandom sequence; and
means for transmitting a signal generated based at least in part on the pseudorandom sequence.

54. An apparatus for wireless communication at a wireless device, comprising:
means for generating a plurality of bit subsets based at least in part on a plurality of ordered information bits;
means for generating an orthogonal cover code based at least in part on a first subset of the plurality of bit subsets;
means for applying the orthogonal cover code to an input pseudorandom sequence to generate a plurality of orthogonal or pseudo-orthogonal random sequences; and
means for generating a reference signal based at least in part on the plurality of orthogonal or pseudo-orthogonal random sequences.

55. A non-transitory computer-readable medium storing code for wireless communication at a wireless device, the code comprising instructions for a processor to cause the wireless device to:
segment a bit sequence of information bits into a plurality of bit groups;
map each bit group of the plurality of bit groups to a respective symbol to generate a plurality of ordered information symbols;
encode the plurality of ordered information symbols to generate a plurality of codewords;
demap each codeword of the plurality of codewords to generate a plurality of sequences;
multiplex the plurality of sequences to generate a pseudorandom sequence; and
transmit a signal generated based at least in part on the pseudorandom sequence.

56. A non-transitory computer-readable medium storing code for wireless communication at a wireless device, the code comprising instructions for a processor to cause the wireless device to:
generate a plurality of bit subsets based at least in part on a plurality of ordered information bits;
generate an orthogonal cover code based at least in part on a first subset of the plurality of bit subsets;
apply the orthogonal cover code to an input pseudorandom sequence to generate a plurality of orthogonal or pseudo-orthogonal random sequences; and
generate a reference signal based at least in part on the plurality of orthogonal or pseudo-orthogonal random sequences.
